(19) United States
(12) Patent Application Publication
(10) Pub. No.: US 2025/0048707 A1
(43) Pub. Date: Feb. 6, 2025

(54) SEMICONDUCTOR DEVICES

(71) Applicant: SAMSUNG ELECTRONICS CO., LTD., Suwon-si (KR)

(72) Inventors: Donghoon KWON, Suwon-si (KR); Jinwoo BAE, Suwon-si (KR)

(21) Appl. No.: 18/604,871

(22) Filed: Mar. 14, 2024

(30) Foreign Application Priority Data
Aug. 1, 2023 (KR) 10-2023-0100703

(51) Int. Cl. H01L 29/66; H01L 23/528; H10B 12/00

(52) U.S. Cl. CPC H01L 29/6656; H01L 23/528; H10B 12/315; H10B 12/50

(57) ABSTRACT

A semiconductor device comprising: a substrate; a plurality of gate structures on the substrate, wherein the plurality of gate structures includes a first gate structure and a second gate structure that is adjacent the first gate structure; spacer structures on opposite sidewalls of the first gate structure; wherein the spacer structures comprise: insulating spacers on the opposite sidewalls of the first gate structure; an inner protective layer on the insulating spacers and an upper surface of the first gate structure; and an outer protective layer on at least a portion of the inner protective layer, an insulating filling layer on the spacer structures, wherein the insulating filling layer is between the first gate structure and the second gate structure; and an upper capping layer on an upper surface of the insulating filling layer, wherein the upper capping layer includes a same material as the insulating filling layer.

### CROSS-REFERENCE TO RELATED APPLICATION

This application is based on and claims priority under 35 U.S.C. § 119 to Korean Patent Application No. 10-2023-0100703, filed on Aug. 1, 2023, in the Korean Intellectual Property Office, the disclosure of which is incorporated by reference herein in its entirety.

### BACKGROUND

The inventive concepts of the present disclosures relates to semiconductor devices, and more particularly, to semiconductor devices including contact plugs of a peripheral circuit area.

As electronic products need to become more compact, multi-functional, and high-performance, there is a demand for higher capacity and higher integration of semiconductor devices. As semiconductor devices become more capacitive and highly integrated, it is becoming increasingly difficult to secure the structural stability of components that constitute semiconductor devices.

### SUMMARY

The inventive concepts of the present disclosures may provide a semiconductor devices in which contact plugs of a peripheral circuit area have improved structural stability.

In addition, the problems to be solved by the inventive concepts of the present disclosures are not limited to the aforementioned problems, and other problems may be clearly understood by those skilled in the art from the following description.

According to an aspect of the inventive concepts of the present disclosures, there is provided a semiconductor device including a substrate; a plurality of gate structures on the substrate, wherein the plurality of gate structures includes a first gate structure and a second gate structure that is adjacent the first gate structure; spacer structures on opposite sidewalls of the first gate structure; wherein the spacer structures comprise: insulating spacers on the opposite sidewalls of the first gate structure; an inner protective layer on the insulating spacers and an upper surface of the first gate structure; and an outer protective layer on at least a portion of the inner protective layer, an insulating filling layer on the spacer structures, wherein the insulating filling layer is between the first gate structure and the second gate structure; and an upper capping layer on an upper surface of the insulating filling layer, wherein the upper capping layer includes a same material as the insulating filling layer.

According to another aspect of the inventive concepts of the present disclosures, there is provided a semiconductor device including a substrate; a plurality of gate structures on the substrate; spacer structures on opposite sidewalls of the plurality of gate structures, respectively; wherein the spacer structures comprise: a plurality of insulating spacers on the opposite sidewalls of the plurality of gate structures, respectively; an inner protective layer on the plurality of insulating spacers and upper surfaces of the plurality of gate structures; and an outer protective layer on at least a portion of the inner protective layer, an insulating filling layer between adjacent gate structures among the plurality of gate structures, wherein the insulating filling layer is on the spacer structures; an upper capping layer on an upper surface of the insulating filling layer; and a contact plug that extends in the insulating filling layer and the upper capping layer in a first direction that is perpendicular to an upper surface of the substrate, wherein the insulating filling layer includes a same material as the upper capping layer.

According to another aspect of the inventive concepts of the present disclosures, there is provided a semiconductor device including a substrate; a plurality of gate structures on the substrate; spacer structures on opposite sidewalls of the plurality of gate structures, respectively; wherein the spacer structures comprise: a plurality of insulating spacers on the opposite sidewalls of the plurality of gate structures, respectively; an inner protective layer on the plurality of insulating spacers and upper surfaces of the plurality of gate structures; and an outer protective layer on at least a portion of the inner protective layer, an insulating filling layer between adjacent gate structures among the plurality of gate structures, wherein the insulating filling layer is on the spacer structures; an upper capping layer on the insulating filling layer; and a contact plug that extends in the insulating filling layer and the upper capping layer in a first direction that is perpendicular to an upper surface of the substrate, wherein the insulating filling layer includes a same material as the upper capping layer, and the insulating filling layer includes a nitride layer and/or a silicon nitride layer.

### BRIEF DESCRIPTION OF THE DRAWINGS

Embodiments of the inventive concepts of the present disclosures will be more clearly understood from the following detailed description taken in conjunction with the accompanying drawings in which:

FIGS. 1A and 1B are layout views of a semiconductor device according to some embodiments;

FIG. 2A is a cross-sectional view of the semiconductor device taken along line A1-A1′ in FIG. 1A;

FIG. 2B is a cross-sectional view of the semiconductor device taken along line A2-A2′ in FIG. 1A;

FIG. 3A is a cross-sectional view of the semiconductor device taken along line B1-B1′ in FIG. 1B;

FIG. 3B is a cross-sectional view of the semiconductor device taken along line B2-B2′ in FIG. 1B;

FIG. 3C is an enlarged view of a portion AR1 of FIG. 3A;

FIG. 4A is a cross-sectional view for explaining a semiconductor device according to some embodiments;

FIG. 4B is a cross-sectional view for explaining a semiconductor device according to some embodiments;

FIG. 4C is an enlarged view of a portion AR2 of FIG. 4A;

FIG. 5A is a cross-sectional view for explaining a semiconductor device according to some embodiments;

FIG. 5B is a cross-sectional view for explaining a semiconductor device according to some embodiments;

FIG. 5C is an enlarged view of a portion AR3 of FIG. 5A;

FIG. 6A is a cross-sectional view for explaining a semiconductor device according to some embodiments;

FIG. 6B is a cross-sectional view for explaining a semiconductor device according to some embodiments;

FIG. 6C is an enlarged view of a portion AR4 of FIG. 6A; and

FIGS. 7A through 19A and 7B through 19B are cross-sectional views for explaining a method of manufacturing a semiconductor device, according to some embodiments.

### DETAILED DESCRIPTION

Embodiments of the inventive concepts of the present disclosures will now be described more fully with reference to the accompanying drawings. In the accompanying drawings, like reference numerals may refer to like elements, and repeated descriptions of the like elements may be omitted.

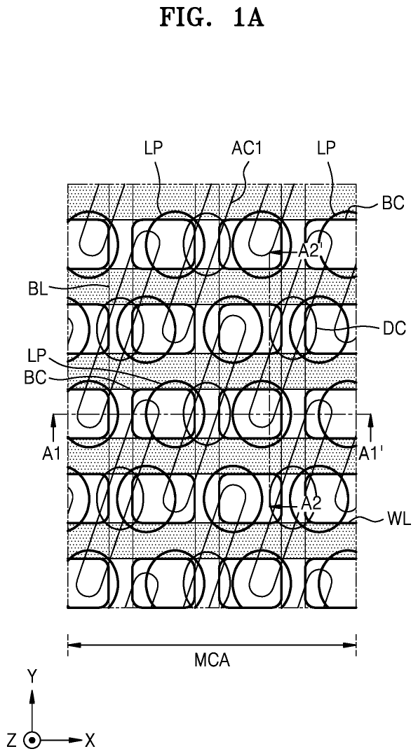

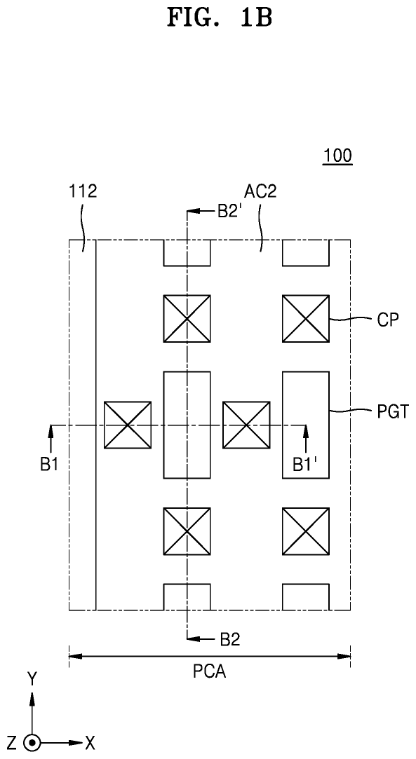

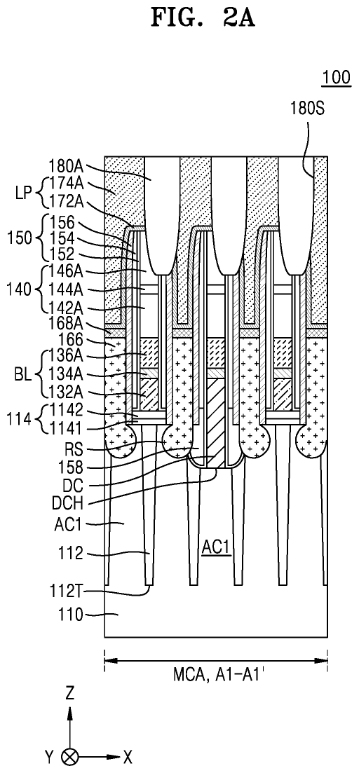

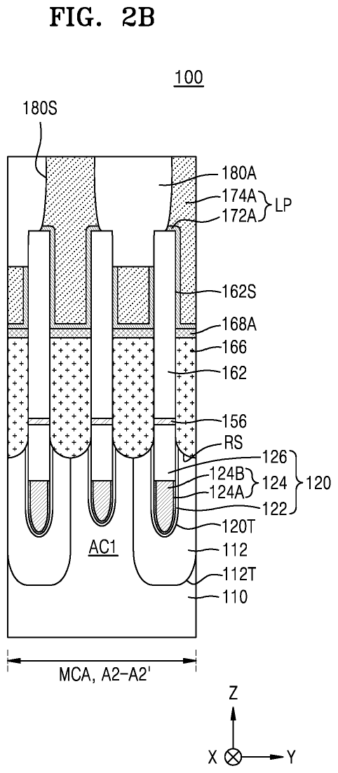

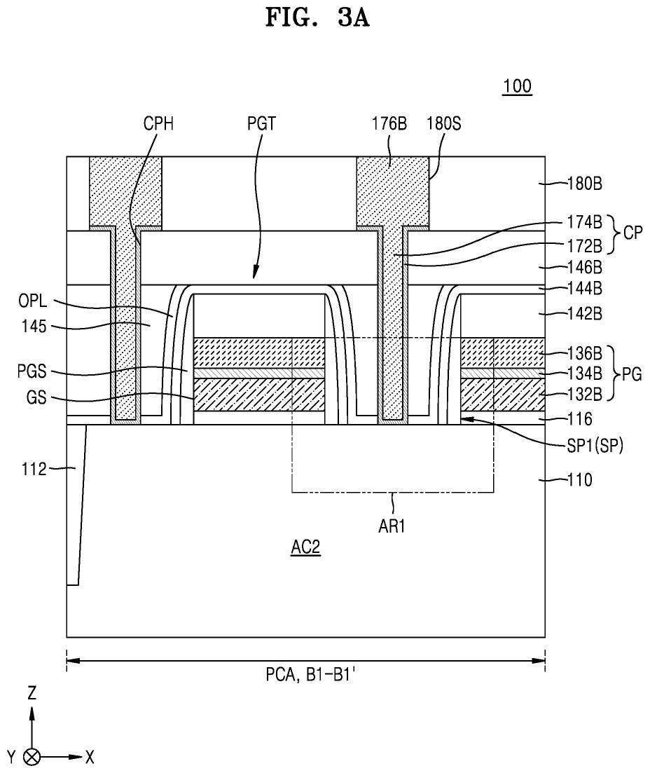

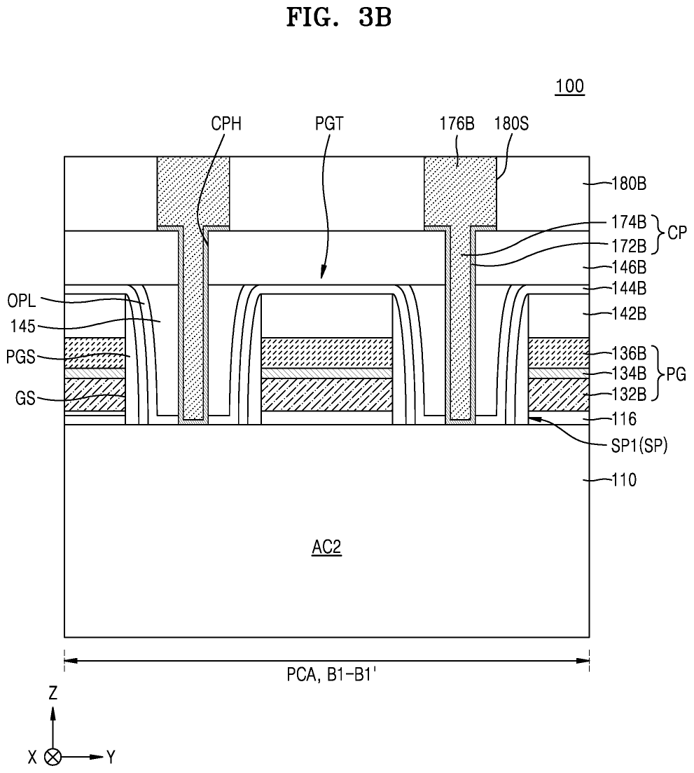

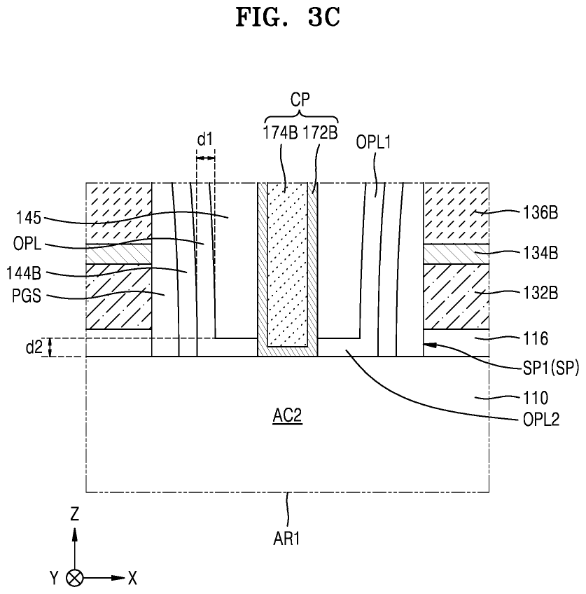

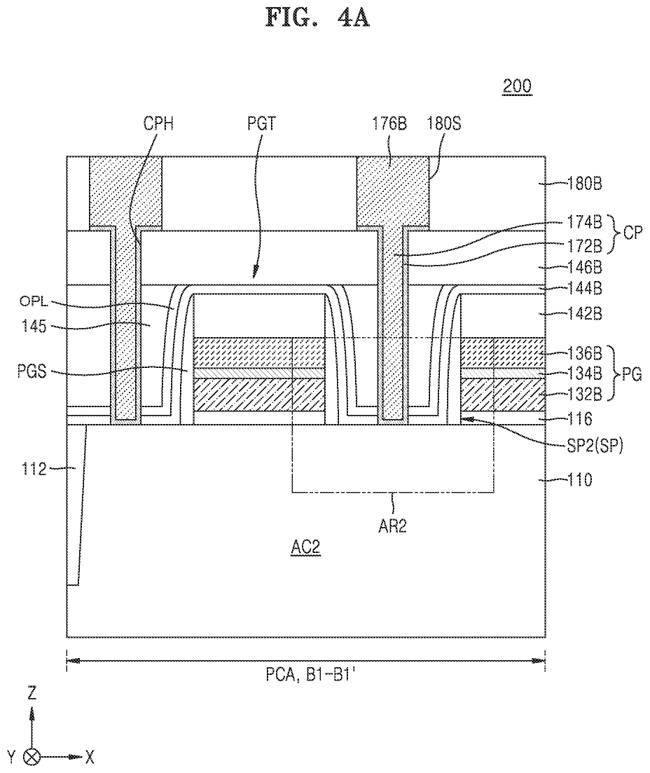

FIGS. 1A and 1B are layout views of a semiconductor device according to some embodiments. FIG. 2A is a cross-sectional view of the semiconductor device taken along line A1-A1′ in FIG. 1A. FIG. 2B is a cross-sectional view of the semiconductor device taken along line A2-A2′ in FIG. 1A. FIG. 3A is a cross-sectional view of the semiconductor device taken along line B1-B1′ in FIG. 1B. FIG. 3B is a cross-sectional view of the semiconductor device taken along line B2-B2′ in FIG. 1B. FIG. 3C is an enlarged view of a portion AR1 of FIG. 3A.

Referring to FIGS. 1A, 1B, 2A, 2B, 3A, 3B, and 3C, a semiconductor device 100 may include a substrate 110 including a cell array area MCA and a peripheral circuit area PCA.

An isolation trench 112T may be formed in the substrate 110, and an isolation layer 112 may be formed within the isolation trench 112T. A plurality of first active regions AC1 may be defined by the isolation layer 112 in the substrate 110 in the cell array area MCA, and a second active region AC2 may be defined by the isolation layer 112 in the substrate 110 in the peripheral circuit area PCA.

Within this specification, a direction in which the substrate 110 extends may be defined as a first horizontal direction X, a direction intersecting the first horizontal direction X may be defined as a second horizontal direction Y, and a direction perpendicular to an upper surface of the substrate 110 may be defined as a vertical direction Z. For example, an upper surface of the substrate 110 may extend in the first horizontal direction X and the second horizontal direction Y. The first horizontal direction X and the second horizontal direction Y may be parallel with the upper surface of the substrate 110. The vertical direction Z may be perpendicular to the upper surface of the substrate 110.

Each of the plurality of first active regions AC1 may be arranged to have a long axis diagonally with respect to the first horizontal direction X (e.g., X direction) and the second horizontal direction Y (e.g., Y direction). A plurality of word lines WL may each extend in parallel to each other in the first horizontal direction X over the plurality of first active regions AC1. On the plurality of word lines WL, a plurality of bit lines BL may extend in parallel to each other in the second horizontal direction Y. The plurality of bit lines BL may be connected (e.g., electrically connected) to the plurality of first active regions AC1 via direct contacts DC. For example, the plurality of word lines WL may overlap the plurality of first active regions AC1 in the vertical direction Z, and the plurality of bit lines BL may overlap the plurality of word lines WL in the vertical direction Z. As used herein, “an element A overlapping an element B in a direction C” (or similar language) means that there is at least one line that extends in the direction C and intersects both the elements A and B. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present. As used herein, the term “and/or” includes any and all combinations of one or more of the associated listed items.

A plurality of buried contacts BC may be formed between two bit lines BL adjacent to each other among the plurality of bit lines BL. The plurality of buried contacts BC may be arranged in a line in the first horizontal direction X and the second horizontal direction Y. A plurality of landing pads LP may be formed on the plurality of buried contacts BC. The plurality of buried contacts BC and the plurality of landing pads LP may connect (e.g., electrically connect) lower electrodes (not shown) of capacitors formed over (on) the plurality of bit lines BL to the first active regions AC1. A landing pad LP among the plurality of landing pads LP may be arranged to partially overlap (in the vertical direction Z) a buried contact BC among the plurality of buried contacts BC. Herein the terms “lower”, “higher”, “lower level”, “higher level”, and the like may refer to a relative distance from the upper/lower surface of the substrate 110 in the vertical direction Z. For example, when an element A is described as lower than an element B, the element A may be closer than the element B to the upper/lower surface of the substrate 110 in the vertical direction Z.

The substrate 110 may include silicon, for example, single-crystalline silicon, polycrystalline silicon, and/or amorphous silicon. According to some embodiments, the substrate 110 may include, for example, Ge, SiGe, SiC, GaAs, InAs, and/or InP. According to some embodiments, the substrate 110 may include a conductive region, for example, an impurity-doped well or an impurity-doped structure. The isolation layer 112 may include, for example, an oxide layer, a nitride layer, and/or a combination thereof.

In the cell array area MCA, a plurality of word line trenches 120T each extending in the first horizontal direction X may be disposed in the substrate 110, and the plurality of word line trenches 120T may be (at least partially) filled with a plurality of buried gate structures 120. Each of the plurality of buried gate structures 120 may include a gate dielectric layer 122, a buried gate electrode 124, and a capping insulating layer 126. The buried gate electrodes 124 included in the plurality of buried gate structures 120 may correspond to the plurality of word lines WL of FIG. 1. The gate dielectric layer 122 may include, for example, a silicon oxide layer, a silicon nitride layer, a silicon oxynitride layer, an oxide/nitride/oxide (ONO) layer, and/or a high-k dielectric film having a higher dielectric constant than the silicon oxide layer.

The buried gate electrode 124 may include a work function control layer 124A conformally disposed on a lower inner wall of the plurality of word line trenches 120T, and a buried conductive layer 124B filling a portion between the lower inner wall of the plurality of word line trenches 120T. For example, the work function control layer 124A may at least partially extend around (e.g., at least partially surround) the buried conductive layer 124B. For example, the work function control layer 124A may include, for example, a metal, a metal nitride, and/or a metal carbide, such as Ti, TiN, TiAlN, TiAlC, TiAlCN, TiSiCN, Ta, TaN, TaAlN, TaAlCN, and/or TaSiCN, and the buried conductive layer 124B may include, for example, W, WN, TiN, TaN, and/or doped polysilicon. The capping insulating layer 126 may be disposed on upper surfaces of the gate dielectric layer and the buried gate electrode 124. The capping insulating layer 126 may include, for example, a silicon oxide layer, a silicon nitride layer, a silicon oxynitride layer, and/or a combination thereof.

A buffer layer 114 may be formed on the substrate 110 in the cell array area MCA. The buffer layer 114 may include a first insulating layer 1141 and a second insulating layer 1142. Each of the first and second insulating layers 1141 and 1142 may include, for example, an oxide layer, a nitride layer, and/or a combination thereof.

A plurality of direct contacts DC may be formed in a plurality of direct contact plug holes DCH on the substrate 110. The plurality of direct contacts DC may be connected (e.g., electrically connected) to the plurality of first active regions AC1. The plurality of direct contacts DC may include, for example, doped polysilicon. For example, the plurality of direct contacts DC may include polysilicon including n-type impurities, such as phosphorus (P), arsenic (As), bismuth (Bi), and/or antimony (Sb), at a relatively high concentration.

The plurality of bit lines BL may each extend in the second horizontal direction Y on the substrate 110 and the plurality of direct contacts DC. The plurality of bit lines BL may be connected (e.g., electrically connected) to the first active region AC via direct contacts DC, respectively. Each of the plurality of bit lines BL may include a lower conductive pattern 132A, an intermediate conductive pattern 134A, and an upper conductive pattern 136A sequentially stacked on the substrate 110. The lower conductive pattern 132A may include, for example, doped polysilicon. Each of the intermediate conductive pattern 134A and the upper conductive pattern 136A may include, for example, TiN, TiSiN, W, W silicide, and/or a combination thereof. According to some embodiments, the intermediate conductive pattern 134A may include, for example, TiN, TiSiN, and/or a combination thereof, and the upper conductive pattern 136A may include, for example, W.

The plurality of bit lines BL may be covered with the plurality of insulation capping structures 140, respectively. Each of the plurality of insulation capping structures 140 may include a lower capping pattern 142A, an intermediate capping pattern 144A, and an upper capping pattern 146A. The lower capping pattern 142A, the intermediate capping pattern 144A, and the upper capping pattern 146A may include, for example, a silicon nitride layer. The plurality of insulation capping structures 140 may extend in the second horizontal direction Y on the plurality of bit lines BL.

A cell spacer structure 150 may be disposed on both (e.g., opposite) sidewalls of each of the plurality of bit lines BL. The cell spacer structure 150 may extend in the second horizontal direction Y on both (e.g., opposite) sidewalls of the plurality of bit lines BL, and a portion of the cell spacer structure 150 may extend to the inside of a direct contact plug hole DCH and thus at least partially cover (e.g., overlap) both (e.g., opposite) sidewalls of a direct contact DC. In some embodiments, the cell spacer structure 150 may be on both (e.g., opposite) sidewalls of each of the plurality of insulation capping structures 140.

According to some embodiments, the cell spacer structure 150 may include a first spacer layer 152, a second spacer layer 154, and a third spacer layer 156. The first spacer layer 152 may be conformally disposed on sidewalls of the plurality of bit lines BL, sidewalls of the insulation capping structure 140, and/or an inner wall (e.g., inner sidewalls) of the direct contact plug hole DCH. The second spacer layer 154 and the third spacer layer 156 may be sequentially disposed on the first spacer layer 152. According to some embodiments, the first and third spacer layers 152 and 156 may include, for example, silicon nitride, and the second spacer layer 154 may include, for example, silicon oxide. According to some embodiments, the first and third spacer layers 152 and 156 may include, for example, silicon nitride, and the second spacer layer 154 may include, for example, air or a low-k dielectric material. The term “air” used herein may refer to a space including the atmospheric air, or other gases that may exist during a manufacturing process.

A buried insulating layer 158 may be disposed on the first spacer layer 152, may extend around (e.g., at least partially surround) a lower portion of the direct contact DC, and may fill a remaining space of the direct contact plug hole DCH. The buried insulating layer 158 may include, for example, silicon nitride, silicon oxynitride, silicon oxide, or a combination thereof.

The direct contact DC may be formed within the direct contact plug hole DCH formed in the substrate 110, and may extend to a level higher than the upper surface of the substrate 110. For example, an upper surface of the direct contact DC may be disposed at the same level as an upper surface of the lower conductive pattern 132A, and the upper surface of the direct contact DC may be connected (e.g., electrically connected) to a lower surface of the intermediate conductive pattern 134A. A lower surface of the direct contact DC may be disposed at a lower level than the upper surface of the substrate 110.

A plurality of insulating fences 162 and a plurality of conductive plugs 166 may be arranged in a row in the second horizontal direction Y between a pair of the plurality of bit lines BL that are adjacent to each other. The plurality of insulating fences 162 may be disposed on capping insulating layers 126 disposed in respective upper portions of the plurality of word line trenches 120T, and may have upper surfaces disposed at the same level as an upper surface of the insulation capping structure 140 (e.g., an upper surface of the upper capping pattern 146A). Each of the plurality of conductive plugs 166 may extend from a recess space RS formed in the substrate 110, in the vertical direction (Z direction). Both (e.g., opposite) sidewalls of each of the plurality of conductive plugs 166 may be spaced apart (e.g., insulated) from each other by the plurality of insulating fences 162 in the second horizontal direction Y. The plurality of insulating fences 162 may include, for example, a silicon nitride layer. The plurality of conductive plugs 166 may constitute the plurality of buried contacts BC of FIG. 1.

A plurality of metal silicide layers 168A and a plurality of landing pads LP may be formed on the plurality of conductive plugs 166. The metal silicide layers 168A and the landing pads LP may be arranged to vertically overlap (e.g., overlap in the vertical direction Z) the conductive plugs 166. Each of the metal silicide layers 168A may include, for example, cobalt silicide, nickel silicide, and/or manganese silicide. The plurality of landing pads LP may be connected (e.g., electrically connected) to the conductive plugs 166, respectively, through the metal silicide layers 168A. Each of the plurality of landing pads LP may include a conductive barrier layer 172A and a conductive layer 174A.

The plurality of landing pads LP may be spaced apart (e.g., electrically insulated) from each other by insulating patterns 180A that (at least partially) fill insulation spaces 180S around (extending around) the plurality of landing pads LP. Each insulating pattern 180A may fill an insulating space 180S disposed between a bit line BL and a conductive plug 166, and may be on (e.g., cover or overlap) a sidewall (e.g., both/opposite sidewalls) of the insulation capping structure 140.

According to some embodiments, the insulating pattern 180A may include, for example, silicon nitride, silicon oxynitride, silicon oxide, and/or a combination thereof. According to some embodiments, the insulating pattern 180A may be formed in a two-layered structure of a first material layer (not shown) and a second material layer (not shown), the first material layer may include, for example, a low-k material, such as SiO2, SiOCH, and/or SiOC, and the second material layer may include, for example, silicon nitride and/or silicon oxynitride.

A gate structure PGT may be disposed on the substrate 110 in the peripheral circuit area PCA. The gate structure PGT may include a gate dielectric layer 116, a gate electrode PG, and a gate capping pattern 142B sequentially stacked on the second active region AC2. The gate structure PGT may include a plurality of gate structures. The plurality of gate structures PGT may be spaced apart from each other in the first horizontal direction X.

The gate dielectric layer 116 may include, for example, a silicon oxide layer, a silicon nitride layer, a silicon oxynitride layer, oxide/nitride/oxide (ONO), and/or a high-k dielectric layer having a higher dielectric constant than a silicon oxide layer. The gate electrode PG may include a lower conductive pattern 132B, an intermediate conductive pattern 134B, and an upper conductive pattern 136B. Respective constituent materials of the lower conductive pattern 132B, the intermediate conductive pattern 134B, and the upper conductive pattern 136B in the peripheral circuit area PCA may be the same as those of the lower conductive pattern 132A, the intermediate conductive pattern 134A and the upper conductive pattern 136A included in the bit line BL in the cell array area MCA, respectively. The gate capping pattern 142B may include, for example, a silicon nitride layer.

A spacer structure SP1 may include an insulating spacer PGS, an inner protective layer 144B, and an outer protective layer OPL. The spacer structure SP1 may be disposed on each of both (e.g., opposite) sidewalls of the plurality of gate structures PGT.

A plurality of insulating spacers PGS may be on (e.g., cover or overlap) both (e.g., opposite) sidewalls of the plurality of gate structures PGT, respectively. According to some embodiments, the insulating spacer PGS may include, for example, an oxide layer, a nitride layer, and/or a combination thereof. Although not shown in the drawings, the insulating spacer PGS may include (e.g., be composed of) a double layer. For example, the insulating spacer PGS may include a first insulating spacer (not shown) on (e.g., covering or overlapping) both (e.g., opposite) sidewalls of the gate structure PGT and a second insulating spacer (not shown) on (e.g., covering or overlapping) the first insulating spacer. For example, the second insulating spacer (not shown) may be on (e.g., covering or overlapping) both (e.g., opposite) sidewalls of the first insulating spacer (not shown). According to some embodiments, the first insulating spacer may include, for example, a nitride layer, and the second insulating spacer may include, for example, an oxide layer.

The inner protective layer 144B may be disposed on the insulating spacer PGS. The inner protective layer 144B may be on (e.g., cover or overlap) respective upper surfaces of the plurality of gate structures PGT and upper surfaces of the plurality of insulating spacers PGS. For example, the inner protective layer 144B may be on (e.g., over or overlap) both (e.g., opposite) sidewalls and the upper surface of the insulating spacer PGS and both (e.g., opposite) sidewalls and the upper surface of the gate structure PGT. According to some embodiments, the inner protective layer 144B may include, for example, a silicon nitride layer.

The outer protective layer OPL may be disposed on the inner protective layer 144B. The outer protective layer OPL may cover (or overlap) at least a portion of the inner protective layer 144B. For example, the outer protective layer OPL may be disposed on both (e.g., opposite) sidewalls of the inner protective layer 144B. According to some embodiments, the outer protective layer OPL may not extend to above the gate structure PGT and may not cover the inner protective layer 144B on the gate structure PGT. For example, the outer protective layer OPL may not be disposed on an upper surface of the inner protective layer 144B. The upper surface of the inner protective layer 144B may be exposed from the outer protective layer OPL. According to some embodiments, the outer protective layer OPL may extend to above the gate structure PGT and may cover (or overlap) (the upper surface of) the inner protective layer 144B on the gate structure PGT. A thickness of an extension of the outer protective layer OPL above the gate structure PGT may be adjusted by chemical mechanical polishing (CMP) on the outer protective layer OPL.

According to some embodiments, the outer protective layer OPL may (at least partially) extend along the inner protective layer 144B and thus may be disposed on (e.g., cover or overlap) a portion of the upper surface of the substrate 110. For example, the outer protective layer OPL may cover a portion of the upper surface of the substrate 110 that is not covered by the gate structure PGT, the insulating spacer PGS, and the inner protective layer 144B. The outer protective layer OPL may be disposed on (e.g., cover or overlap) an upper surface of the isolation layer 112. The outer protective layer OPL may contact the portion of the upper surface of the substrate 110 not covered by the gate structure PGT, the insulating spacer PGS, and the inner protective layer 144B, and/or may contact the upper surface of the isolation layer 112.

According to some embodiments, the outer protective layer OPL may include a different material from the inner protective layer 144B and may have a different etch rate from that of the inner protective layer 144B. That is, the outer protective layer OPL and the inner protective layer 144B may have an etch selectivity. According to some embodiments, the outer protective layer OPL may include, for example, an oxide layer, a silicon oxide layer, SiOCN, SiON, SiOC, and/or a combination thereof. Terms “SiOCN”, “SiON”, and “SiOC” used herein refer to materials composed of elements respectively included in these terms, and are not chemical formulas indicating stoichiometric relationships.

On the spacer structure SP1, an insulating filling layer 145 may be disposed. The insulating filling layer 145 may (at least partially) fill a space not filled by the spacer structure SP1, within a space between (adjacent gate structures PGT among) the plurality of gate structures PGT. The outer protective OPL may extend around (e.g., at least partially surround) the insulating filling layer 145. A sidewall of the insulating filling layer 145 may be spaced apart from the inner protective layer 144B with the outer protective layer OPL interposed therebetween, and a lower surface of the insulating filling layer 145 may be spaced apart from (upper surface) the substrate 110 with the outer protective layer OPL interposed therebetween.

According to some embodiments, the insulating filling layer 145 may include a different material from the outer protective layer OPL and may have a different etch rate from that of the outer protective layer OPL. That is, the insulating filling layer 145 and the outer protective layer OPL may have an etch selectivity. The insulating filling layer 145 may include a different material from the inner protective layer 144B and may have a different etch rate from the inner protective layer 144B. That is, the insulating filling layer 145 and the inner protective layer 144B may have an etch selectivity. According to some embodiments, the insulating filling layer 145 may include, for example, a nitride layer and/or a silicon nitride layer.

The upper capping layer 146B may be disposed on the insulating filling layer 145. The upper capping layer 146B may be on (e.g., cover or overlap) an upper surface of the insulating filling layer 145, and may be on (e.g., cover or overlap) a portion of the upper surface of the spacer structure SP1 that is not covered (or overlapped) by the insulating filling layer 145. According to some embodiments, the outer protective layer OPL may not extend to above the gate structure PGT, and the upper capping layer 146B may contact a portion of the inner protective layer 144B that is not covered by the outer protective layer OPL. According to some embodiments, the outer protective layer OPL may extend to above the gate structure PGT, and the upper capping layer 146B may be spaced apart from the inner protective layer 144B with the outer protective layer OPL interposed therebetween. For example, the upper capping layer 146B may be disposed on (e.g., contact) an upper surface of the insulating filling layer 145, an upper surface of inner protective layer 144B, and/or an upper surface of the outer protective layer OPL.

According to some embodiments, the upper capping layer 146B may have a different etch rate from that of the outer protective layer OPL, and may have the same (or substantially the same) etch rate as that of the insulating filling layer 145. That is, the upper capping layer 146B and the outer protective layer OPL may have a first etch selectivity, but the upper capping layer 146B and the insulating filling layer 145 may have no etch selectivity or a second etch selectivity, which is (substantially) less than the first etch selectivity. For example, the upper capping layer 146B may include a silicon nitride layer.

Contact plugs CP may be disposed on the second active region AC2 in the peripheral circuit area PCA. To form a contact plug CP, a contact plug hole CPH extending in (e.g., passing through or penetrating) the upper capping layer 146B, the insulating filling layer 145, and the outer protective layer OPL in the vertical direction Z may be disposed in the peripheral circuit area PCA. The contact plug CP may extend along the contact plug hole CPH to the second active region AC2 of the substrate 110. The contact plug CP may include a conductive barrier layer 172B and a conductive layer 174B, similar to the plurality of landing pads LP formed in the cell array area MCA. The conductive barrier layer 172B may extend conformally along an inner wall (e.g., inner sidewalls and/or an inner lower surface) of the contact plug hole CPH, and the conductive layer 174B may fill a remaining portion of the contact plug hole CPH that is not filled by the conductive barrier layer 172B, on the conductive barrier layer 172B. A metal silicide layer (not shown) may be further included between the contact plug CP and the second active region AC2. The metal silicide layer may include, for example, cobalt silicide, nickel silicide, or manganese silicide.

According to some embodiments, the outer protective layer OPL may include a side portion OPL1 and a lower portion OPL2. The side portion OPL1 of the outer protective layer OPL may (at least partially) extend along the inner protective layer 144B and may be spaced apart from the contact plug CP with the insulating filling layer 145 interposed therebetween. According to some embodiments, a thickness d1 (in the first horizontal direction X) of the side portion OPL1 of the outer protective layer OPL may be within 5 nanometers to 10 nanometers. The lower portion OPL2 of the outer protective layer OPL may extend from the side portion OPL1 of the outer protective layer OPL along the upper surface of the substrate 110, and may contact the contact plug CP (e.g., the conductive barrier layer 172B). According to some embodiments, a thickness d2 (in the vertical direction Z) of the lower portion OPL2 of the outer protective layer OPL may be within 5 nanometers to 10 nanometers. Although the side portion OPL1 and the lower portion OPL2 of the outer protective layer OPL are shown as extending conformally, the side portion OPL1 and the lower portion OPL2 of the outer protective layer OPL are not limited to the conformal extension. The thickness d1 of the side portion OPL1 of the outer protective layer OPL and the thickness d2 of the lower portion OPL2 of the outer protective layer OPL may be different from each other, and embodiments of the inventive concept are not limited thereto. The inner protective layer 144B may be spaced apart from the contact plug CP with the outer protective layer OPL and/or the insulating filling layer 145 interposed therebetween. The insulating spacer PGS may be spaced apart from the contact plug CP with the inner protective layer 144B, the outer protective layer OPL, and/or the insulating filling layer 145 interposed therebetween.

The plurality of contact plugs CP may be connected (e.g., electrically connected) to a plurality of peri bit lines 176B. Each of the plurality of peri bit lines 176B may be connected (e.g., electrically connected) to the second active region AC2 via the contact plug CP. The plurality of peri bit lines 176B may be spaced apart (e.g., electrically insulated) from each other by insulating patterns 180B around (e.g., extending around) the plurality of peri bit lines 176B. The insulating patterns 180B may fill a space between (adjacent peri bit lines 176B among) the plurality of peri bit lines 176B, and may cover both (e.g., opposite) sidewalls of (the adjacent peri bit lines 176B among) the plurality of peri bit lines 176B.

According to some embodiments, each insulating pattern 180B may include, for example, silicon nitride, silicon oxynitride, silicon oxide, and/or a combination thereof. According to some embodiments, the insulating pattern 180B may include a two-layered structure of a first material layer (not shown) and a second material layer (not shown), the first material layer may include, for example, a low-k material, such as SiO2, SiOCH, and/or SiOC, and the second material layer may include, for example, silicon nitride and/or silicon oxynitride.

According to a comparative example, the insulating filling layer 145 may have a different etch rate from that of the upper capping layer 146B. That is, in this comparative example, the insulating filling layer 125 and the upper capping layer 146B may have an etch selectivity. Because the insulating filling layer 145 has a different etch rate from that of the upper capping layer 146B, diameters of a portion of the contact plug hole CPH that contacts the insulating filling layer 145 in the first horizontal direction X and the second horizontal direction Y may be greater than diameters of a portion of the contact plug hole CPH that contacts the upper capping layer 146B in the first horizontal direction X and the second horizontal direction Y, during etching of the contact plug hole CPH. Because the diameters of the portion of the contact plug hole CPH that contacts the insulating filling layer 145 are greater than those of the portion of the contact plug hole CPH that contacts the upper capping layer 146B, a void may be formed inside a portion of the contact plug CP connected (e.g., contacted) to the insulating filling layer 145.

According to some embodiments of the inventive concepts of the present disclosures, because the insulating filling layer 145 has the same etch rate as that of the upper capping layer 146B, the diameters of the portion of the contact plug hole CPH that contacts the insulating filling layer 145 in the first horizontal direction X and the second horizontal direction Y may be formed to be substantially the same as those of the portion of the contact plug hole CPH that contacts the upper capping layer 146B in the first horizontal direction X and the second horizontal direction Y, during etching of the contact plug hole CPH. Accordingly, voids may be reduced (e.g., prevented) from being formed inside the portion of the contact plug CP that contacts the insulating filling layer 145, and, ultimately, the structural stability of the semiconductor device 100 may be improved.

According to some embodiments of the inventive concepts of the present disclosures, the insulating filling layer 145 may have the same etch rate as that of the upper capping layer 146B. However, because the outer protective layer OPL is interposed between the insulating filling layer 145 and the inner protective layer 144B and has a different etch rate from those of the insulating filling layer 145 and the inner protective layer 144B, and thus the outer protective layer OPL may be used as an etch stop layer when CMP is performed on the insulating filling layer 145, the gate structure PGT may be prevented from being damaged by CMP.

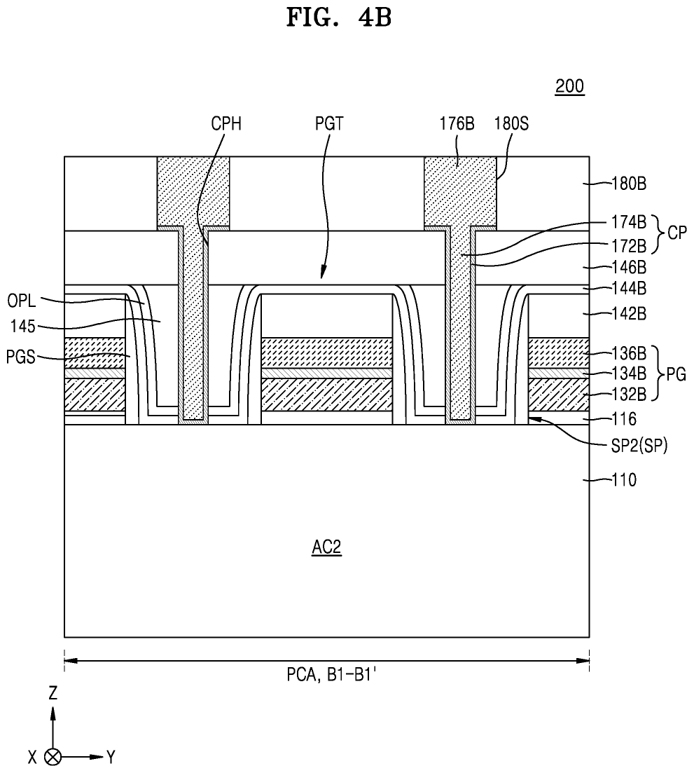

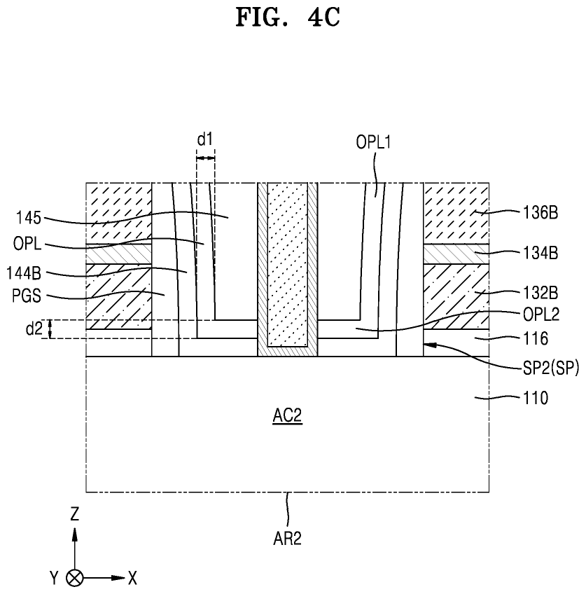

FIG. 4A is a cross-sectional view for explaining a semiconductor device according to some embodiments.

FIG. 4B is a cross-sectional view for explaining a semiconductor device according to some embodiments.

FIG. 4C is an enlarged view of a portion AR2 of FIG. 4A.

Referring to FIGS. 4A, 4B, and 4C, a semiconductor device 200 has a similar (e.g., an almost the same) structure to that of the semiconductor device 100 illustrated in FIGS. 1, 2A, 2B, 3A, 3B, and 3C. However, the semiconductor device 200 may include a spacer structure SP2 instead of the spacer structure SP1. A description of a configuration of FIGS. 4A through 4C that is the same as or similar to the semiconductor device 100 illustrated in FIGS. 1, 2A, 2B, 3A, 3B, and 3C may now be simplified or omitted, and differences between the semiconductor device 100 and the semiconductor device 200 will now be described in detail.

The semiconductor device 200 may include a cell array area MCA and a peripheral circuit area PCA, and a gate structure PGT may be formed on a second active region AC2 in the peripheral circuit area PCA. The gate structure PGT may include a gate dielectric layer 116, a gate electrode PG, and a gate capping pattern 142B sequentially stacked on the second active region AC2. The gate structure PGT may include a plurality of gate structures. The plurality of gate structures PGT may be spaced apart from each other in the first horizontal direction X.

The spacer structure SP2 may include an insulating spacer PGS, an inner protective layer 144B, and an outer protective layer OPL. The spacer structure SP2 may be disposed on each of both (e.g., opposite) sidewalls of the plurality of gate structures PGT.

A plurality of insulating spacers PGS may be on (e.g., cover or overlap) both (e.g., opposite) sidewalls of the plurality of gate structures PGT, respectively. According to some embodiments, each insulating spacer PGS may include, for example, an oxide layer, a nitride layer, and/or a combination thereof. Although not shown in the drawings, the insulating spacer PGS may include a double layer. For example, the insulating spacer PGS may include a first insulating spacer (not shown) on (e.g., covering or overlapping) both (e.g., opposite) sidewalls of the gate structure PGT and a second insulating spacer (not shown) on (e.g., covering or overlapping) the first insulating spacer. According to some embodiments, the first insulating spacer may include, for example, a nitride layer, and the second insulating spacer may include, for example, an oxide layer.

The inner protective layer 144B may be disposed on the insulating spacer PGS. The inner protective layer 144B may be on (e.g., cover or overlap) respective upper surfaces of the plurality of gate structures PGT, and the plurality of insulating spacers PGS. For example, the inner protective layer 144B may be on an upper surface of the gate capping pattern 142B and both (e.g., opposite) sidewalls of the insulating spacer PGS. According to some embodiments, the inner protective layer 144B may include, for example, a silicon nitride layer.

According to some embodiments, the inner protective layer 144B may (at least partially) extend along the insulating spacer PGS and thus may be on (e.g., cover or overlap) a portion of the upper surface of the substrate 110. For example, the inner protective layer 144B may be on (e.g., cover or overlap) a portion of the upper surface of the substrate 110 that is not covered (or not overlapped) by the gate structure PGT and the insulating spacer PGS. The inner protective layer 144B may be on (e.g., cover or overlap) an upper surface of the isolation layer 112. The inner protective layer 144B may contact the portion of the upper surface of the substrate 110 not covered (or not overlapped) by the gate structure PGT and the insulating spacer PGS. The inner protective layer 144B may contact the upper surface of the isolation layer 112.

The outer protective layer OPL may be disposed on the inner protective layer 144B. The outer protective layer OPL may cover (or overlap) at least a portion of the inner protective layer 144B. According to some embodiments, the outer protective layer OPL may not extend to above the gate structure PGT and may not cover (or may not overlap) the inner protective layer 144B on the gate structure PGT. For example, the outer protective layer OPL may not be on an upper surface of the inner protective layer 144B or the upper surface of the gate capping pattern 142B. According to some embodiments, the outer protective layer OPL may extend to above the gate structure PGT to cover (or overlap) the inner protective layer 144B on the gate structure PGT. For example, the outer protective layer OPL may be on the upper surface of the inner protective layer 144B or the upper surface of the gate capping pattern 142B. A thickness of an extension of the outer protective layer OPL above the gate structure PGT may be adjusted by CMP on the outer protective layer OPL.

According to some embodiments, the outer protective layer OPL may (at least partially) extend along the inner protective layer 144B, and may be on (e.g., cover or overlap) a portion of the upper surface of the substrate 110. The inner protective layer 144B may be disposed between the outer protective layer OPL and the portion of the upper surface of the substrate 110. For example, the outer protective layer OPL may cover (or overlap) a portion of the upper surface of the substrate 110 that is not covered (or not overlapped) by the gate structure PGT, the insulating spacer PGS, and the inner protective layer 144B. The outer protective layer OPL may be on (e.g., cover or overlap) an upper surface of the isolation layer 112. The inner protective layer 144B may be between the outer protective layer OPL and the upper surface of the isolation layer 112. The outer protective layer OPL may be spaced apart from the upper surface of the substrate 110 and the upper surface of the isolation layer 112 with the inner protective layer 144B interposed therebetween.

According to some embodiments, the outer protective layer OPL may have a different etch rate from that of the inner protective layer 144B. That is, the outer protective layer OPL and the inner protective layer 144B may have an etch selectivity. According to some embodiments, the outer protective layer OPL may include, for example, an oxide layer, a silicon oxide layer, SiOCN, SiON, SiOC, and/or a combination thereof.

On the spacer structure SP2, an insulating filling layer 145 may be disposed. The insulating filling layer 145 may (at least partially) fill a remaining space not filled by the spacer structure SP2, within a space between (adjacent gate structures PGT among) the plurality of gate structures PGT. The outer protective layer OPL may extend around (e.g., at least partially surround) the insulating filling layer 145. For example, a sidewall of the insulating filling layer 145 may be spaced apart from the inner protective layer 144B with the outer protective layer OPL interposed therebetween, and a lower surface of the insulating filling layer 145 may be spaced apart from the inner protective layer 144B with the outer protective layer OPL interposed therebetween.

According to some embodiments, the insulating filling layer 145 may have a different etch rate from that of the outer protective layer OPL, and may have the same (or substantially the same) etch rate as that of the inner protective layer 144B. According to some embodiments, the insulating filling layer 145 may include, for example, a nitride layer and/or a silicon nitride layer.

The upper capping layer 146B may be disposed on the insulating filling layer 145. The upper capping layer 146B may be on (e.g., cover or overlap) an upper surface of the insulating filling layer 145, and may cover (or overlap) a portion of the upper surface of the spacer structure SP2 that is not covered (or not overlapped) by the insulating filling layer 145. According to some embodiments, the outer protective layer OPL may not extend to above the gate structure PGT, and the upper capping layer 146B may contact a portion of the inner protective layer 144B that is not covered by the outer protective layer OPL. For example, the upper capping layer 146B may contact an upper surface of the inner protective layer 144B. According to some embodiments, the outer protective layer OPL may extend to above the gate structure PGT, and the upper capping layer 146B may be spaced apart from (the upper surface of) the inner protective layer 144B with the outer protective layer OPL interposed therebetween.

According to some embodiments, the upper capping layer 146B may have a different etch rate from that of the outer protective layer OPL, and may have the same (or substantially the same) etch rate as that of the insulating filling layer 145. For example, the upper capping layer 146B may include a silicon nitride layer.

Contact plugs CP may be disposed on the second active region AC2 in the peripheral circuit area PCA. To form a contact plug CP, a contact plug hole CPH extending in (e.g., passing through or penetrating) the upper capping layer 146B, the insulating filling layer 145, and the outer protective layer OPL in the vertical direction Z may be disposed in the peripheral circuit area PCA. The contact plug CP may extend along the contact plug hole CPH to the second active region AC2 of the substrate 110.

According to some embodiments, the outer protective layer OPL may include a side portion OPL1 and a lower portion OPL2. The side portion OPL1 of the outer protective layer OPL may (at least partially) extend along a sidewall of the inner protective layer 144B, and may be spaced apart from the contact plug CP with the insulating filling layer 145 interposed therebetween. According to some embodiments, a thickness d1 of the side portion OPL1 of the outer protective layer OPL (in the first horizontal direction X) may be within 5 nanometers to 10 nanometers. The lower portion OPL2 of the outer protective layer OPL may extend from the side portion OPL1 of the outer protective layer OPL along the upper surface of the inner protective layer 144B, and may contact the contact plug CP. According to some embodiments, a thickness d2 of the lower portion OPL2 of the outer protective layer OPL (in the vertical direction Z) may be within 5 nanometers to 10 nanometers. Although the side portion OPL1 and the lower portion OPL2 of the outer protective layer OPL are shown as extending conformally, the side portion OPL1 and the lower portion OPL2 of the outer protective layer OPL are limited to the conformal extension. The thickness d1 of the side portion OPL1 of the outer protective layer OPL and the thickness d2 of the lower portion OPL2 of the outer protective layer OPL may be different from each other, and embodiments of the inventive concepts of the present disclosures are not limited thereto. The inner protective layer 144B may (at least partially) extend along the upper surface of the substrate 110 and may contact the contact plug CP. The insulating spacer PGS may be spaced apart from the contact plug CP with the inner protective layer 144B, the outer protective layer OPL, and the insulating filling layer 145 interposed therebetween.

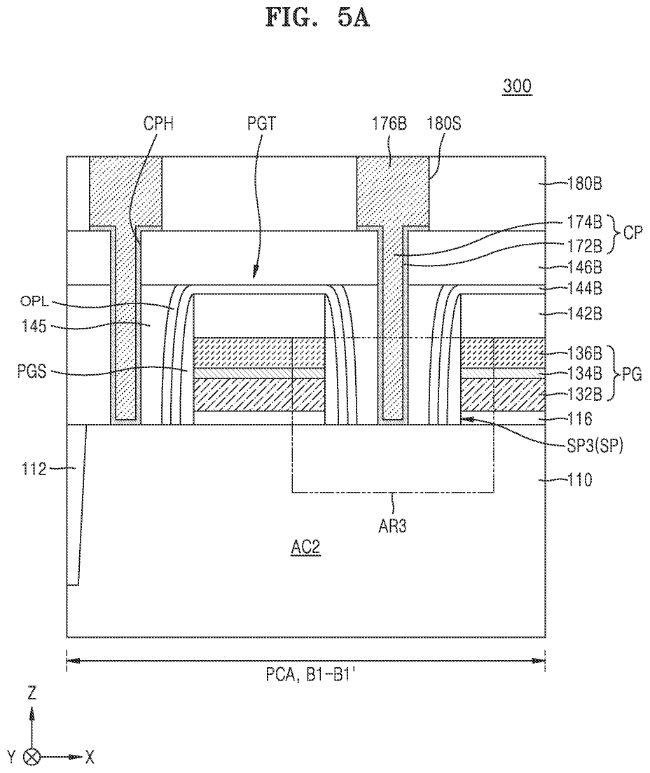

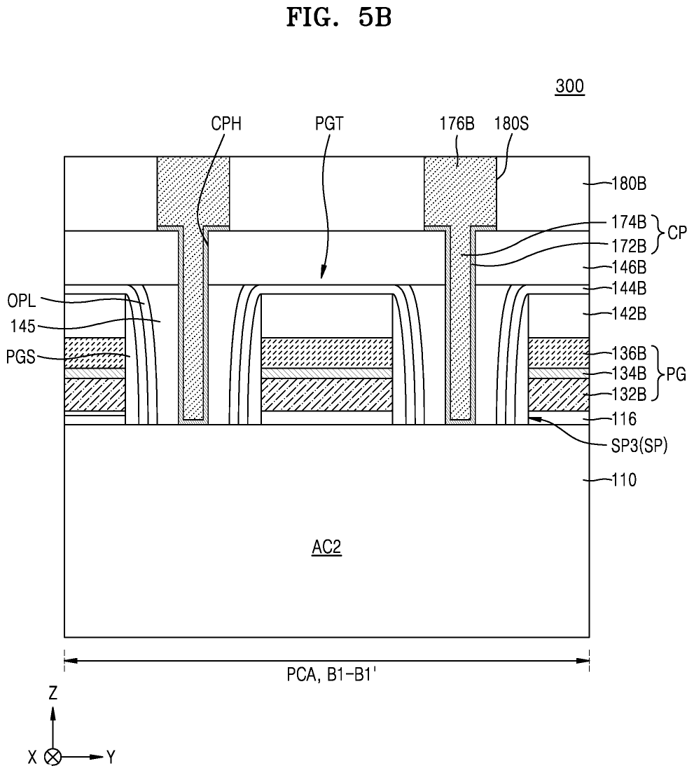

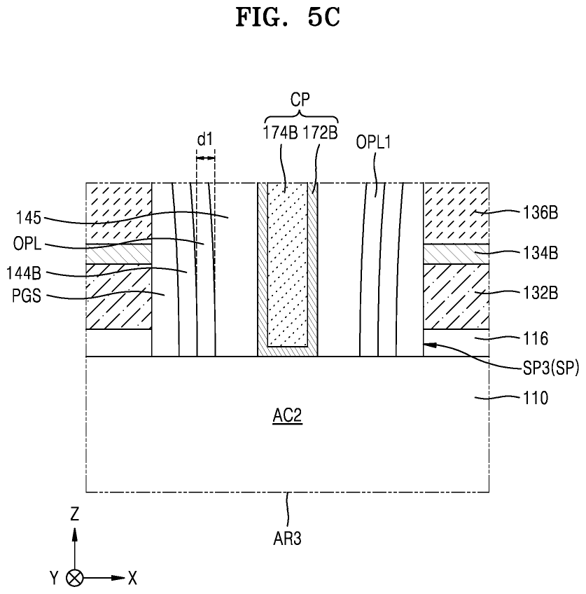

FIG. 5A is a cross-sectional view for explaining a semiconductor device according to some embodiments.

FIG. 5B is a cross-sectional view for explaining a semiconductor device according to some embodiments.

FIG. 5C is an enlarged view of a portion AR3 of FIG. 5A.

Referring to FIGS. 5A, 5B, and 5C, a semiconductor device 300 has a similar structure to (almost the same structure as) that of the semiconductor device 100 illustrated in FIGS. 1, 2A, 2B, 3A, 3B, and 3C. However, the semiconductor device 300 may include a spacer structure SP3 instead of the spacer structure SP1. A description of a configuration of FIGS. 5A through 5C that is the same as the semiconductor device 100 illustrated in FIGS. 1, 2A, 2B, 3A, 3B, and 3C may now be simplified or omitted, and differences between the semiconductor device 100 and the semiconductor device 300 will now be described in detail.

The semiconductor device 300 may include a cell array area MCA and a peripheral circuit area PCA, and a gate structure PGT may be formed on a second active region AC2 in the peripheral circuit area PCA. The gate structure PGT may include a gate dielectric layer 116, a gate electrode PG, and a gate capping pattern 142B sequentially stacked on the second active region AC2. The gate structure PGT may include a plurality of gate structures. The plurality of gate structures PGT may be spaced apart from each other in the first horizontal direction X.

The spacer structure SP3 may include an insulating spacer PGS, an inner protective layer 144B, and an outer protective layer OPL. The spacer structure SP3 may be disposed on each of both (e.g., opposite) sidewalls of the plurality of gate structures PGT.

A plurality of insulating spacers PGS may be on (e.g., cover or overlap) both (e.g., opposite) sidewalls of the plurality of gate structures PGT, respectively. According to some embodiments, each insulating spacer PGS may include, for example, an oxide layer, a nitride layer, and/or a combination thereof. Although not shown in the drawings, the insulating spacer PGS may include a double layer. For example, the insulating spacer PGS may include a first insulating spacer (not shown) on (e.g., covering or overlapping) both (e.g., opposite) sidewalls of the gate structure PGT and a second insulating spacer (not shown) on (e.g., covering or overlapping) the first insulating spacer. According to some embodiments, the first insulating spacer may include, for example, a nitride layer, and the second insulating spacer may include, for example, an oxide layer.

The inner protective layer 144B may be disposed on the insulating spacer PGS. The inner protective layer 144B may be on (e.g., cover or overlap) respective upper surfaces of the plurality of gate structures PGT, and the inner protective layer 144B may be on (e.g., cover or overlap) sidewalls of the plurality of insulating spacers PGS. According to some embodiments, the inner protective layer 144B may include, for example, a silicon nitride layer.

The outer protective layer OPL may be disposed on the inner protective layer 144B. The outer protective layer OPL may cover (or overlap) at least a portion of the inner protective layer 144B. According to some embodiments, the outer protective layer OPL may not extend to above the gate structure PGT and may not be on (e.g., not cover or not overlap) the inner protective layer 144B on the gate structure PGT. For example, the outer protective layer OPL may be on a sidewall of the inner protective layer 144B, and may not be on an upper surface of the inner protective layer 144B. According to some embodiments, the outer protective layer OPL may extend to above the gate structure PGT to cover (or overlap) the inner protective layer 144B on the gate structure PGT. For example, the outer protective layer OPL may be on (e.g., cover or overlap) the upper surface of the inner protective layer 144B. A thickness of an extension of the outer protective layer OPL above the gate structure PGT may be adjusted by CMP on the outer protective layer OPL.

According to some embodiments, the outer protective layer OPL may have a different etch rate from that of the inner protective layer 144B. That is, the outer protective layer OPL and the inner protective layer 144B may have an etch selectivity. According to some embodiments, the outer protective layer OPL may include, for example, an oxide layer, a silicon oxide layer, SiOCN, SiON, SiOC, and/or a combination thereof.

On the spacer structure SP3, an insulating filling layer 145 may be disposed. The insulating filling layer 145 may (at least partially) fill a (remaining) space not filled by the spacer structure SP3, within a space between (adjacent gate structures PGT among) the plurality of gate structures PGT. The outer protective layer OPL may extend around (e.g., at least partially surround) the insulating filling layer 145. A sidewall of the insulating filling layer 145 may be spaced apart from the inner protective layer 144B with the outer protective layer OPL interposed therebetween, and a lower surface of the insulating filling layer 145 may contact (the upper surface of) the substrate 110.

According to some embodiments, the insulating filling layer 145 may (at least partially) extend along the outer protective layer OPL and thus may be on (e.g., cover or overlap) a portion of the upper surface of the substrate 110. For example, the insulating filling layer 145 may be on (e.g., cover or overlap) a portion of the upper surface of the substrate 110 that is between the spacer structure SP3 and the contact plug CP. The insulating filling layer 145 may be on (e.g., cover or overlap) an upper surface of the isolation layer 112. The insulating filling layer 145 may contact a portion of the upper surface of the substrate 110 that is between the spacer structure SP3 and the contact plug CP. The insulating filling layer 145 may contact the upper surface of the isolation layer 112.

According to some embodiments, the insulating filling layer 145 may have a different etch rate from that of the outer protective layer OPL, and may have the same (or substantially the same) etch rate as that of the inner protective layer 144B. According to some embodiments, the insulating filling layer 145 may include, for example, a nitride layer and/or a silicon nitride layer.

The upper capping layer 146B may be disposed on (an upper surface) the insulating filling layer 145. The upper capping layer 146B may cover or overlap an upper surface of the insulating filling layer 145, and may be on (e.g., cover or overlap) a portion of the upper surface of the spacer structure SP3 that is not covered (or overlapped) by the insulating filling layer 145. According to some embodiments, the outer protective layer OPL may not extend to above the gate structure PGT, and the upper capping layer 146B may contact a portion of the inner protective layer 144B that is not covered (or overlapped) by the outer protective layer OPL. For example, the upper capping layer 146B may contact an upper surface of the inner protective layer 144B. According to some embodiments, the outer protective layer OPL may extend to above the gate structure PGT, and the upper capping layer 146B may be spaced apart from (the upper surface of) the inner protective layer 144B with the outer protective layer OPL interposed therebetween.

According to some embodiments, the upper capping layer 146B may have a different etch rate from that of the outer protective layer OPL, and may have the same (or substantially the same) etch rate as that of the insulating filling layer 145. For example, the upper capping layer 146B may include a silicon nitride layer.

Contact plugs CP may be disposed on the second active region AC2 in the peripheral circuit area PCA. To form a contact plug CP, a contact plug hole CPH extending in (e.g., passing through or penetrating) the upper capping layer 146B and the insulating filling layer 145 in the vertical direction Z may be disposed in the peripheral circuit area PCA. The contact plug CP may extend along the contact plug hole CPH to the second active region AC2 of the substrate 110.

According to some embodiments, the outer protective layer OPL may (at least partially) extend along the inner protective layer 144B, and may be spaced apart from the contact plug CP with the insulating filling layer 145 interposed therebetween. According to some embodiments, a thickness d1 (in the first horizontal direction X) of the outer protective layer OPL may be within 5 nanometers to 10 nanometers. Although the outer protective layer OPL is shown as extending conformally, the outer protective layer OPL is not limited to the conformal extension. The inner protective layer 144B may be spaced apart from the contact plug CP with the outer protective layer OPL and the insulating filling layer 145 interposed therebetween. The insulating spacer PGS may be spaced apart from the contact plug CP with the inner protective layer 144B, the outer protective layer OPL, and the insulating filling layer 145 interposed therebetween.

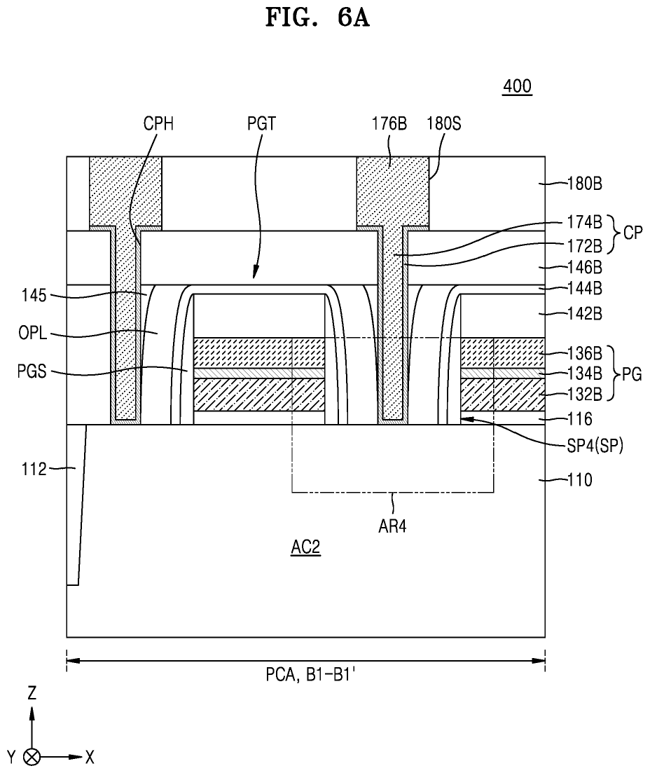

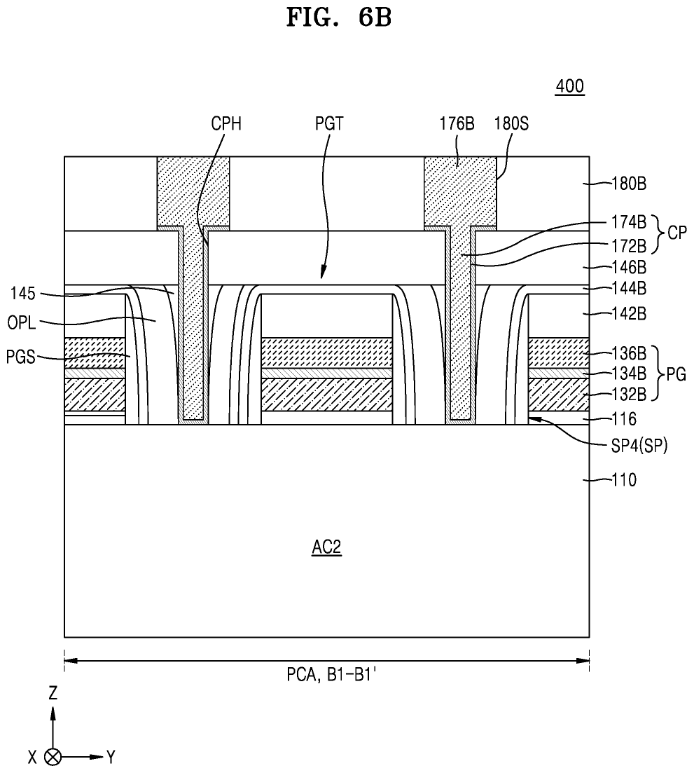

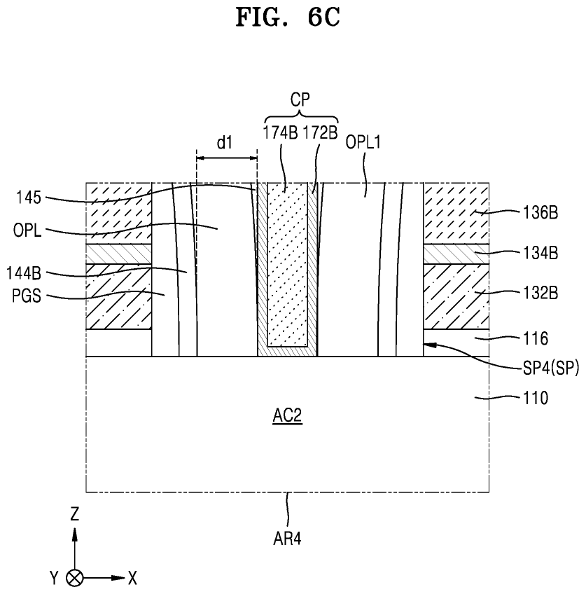

FIG. 6A is a cross-sectional view for explaining a semiconductor device according to some embodiments.

FIG. 6B is a cross-sectional view for explaining a semiconductor device according to some embodiments.

FIG. 6C is an enlarged view of a portion AR4 of FIG. 6A.

Referring to FIGS. 6A, 6B, and 6C, a semiconductor device 400 has a similar structure to (almost the same structure as) that of the semiconductor device 100 illustrated in FIGS. 1, 2A, 2B, 3A, 3B, and 3C. However, the semiconductor device 400 may include a spacer structure SP4 instead of the spacer structure SP1. A description of a configuration of FIGS. 6A through 6C that is the same as the semiconductor device 100 illustrated in FIGS. 1, 2A, 2B, 3A, 3B, and 3C may now be simplified or omitted, and differences between the semiconductor device 100 and the semiconductor device 400 will now be described in detail.

The semiconductor device 400 may include a cell array area MCA and a peripheral circuit area PCA, and a gate structure PGT may be formed on a second active region AC2 in the peripheral circuit area PCA. The gate structure PGT may include a gate dielectric layer 116, a gate electrode PG, and a gate capping pattern 142B sequentially stacked on the second active region AC2. The gate structure PGT may include a plurality of gate structures. The plurality of gate structures PGT may be spaced apart from each other in the first horizontal direction X.

The spacer structure SP4 may include an insulating spacer PGS, an inner protective layer 144B, and an outer protective layer OPL. The spacer structure SP4 may be disposed on each of both (e.g., opposite) sidewalls of the plurality of gate structures PGT.

A plurality of insulating spacers PGS may be on (e.g., cover or overlap) both (e.g., opposite) sidewalls of the plurality of gate structures PGT, respectively. According to some embodiments, each insulating spacer PGS may include, for example, an oxide layer, a nitride layer, and/or a combination thereof. Although not shown in the drawings, the insulating spacer PGS may include a double layer. For example, the insulating spacer PGS may include a first insulating spacer (not shown) on (e.g., covering or overlapping) both (e.g., opposite) sidewalls of the gate structure PGT and a second insulating spacer (not shown) on (e.g., covering or overlapping) the first insulating spacer. According to some embodiments, the first insulating spacer may include, for example, a nitride layer, and the second insulating spacer may include, for example, an oxide layer.

The inner protective layer 144B may be disposed on the insulating spacer PGS. The inner protective layer 144B may be on (e.g., cover or overlap) respective upper surfaces of the plurality of gate structures PGT. The inner protective layer 144B may be on (e.g., cover or overlap) a sidewall of the plurality of insulating spacers PGS. According to some embodiments, the inner protective layer 144B may include, for example, a silicon nitride layer.

The outer protective layer OPL may be disposed on the inner protective layer 144B. The outer protective layer OPL may cover or overlap at least a portion of the inner protective layer 144B. For example, the outer protective layer OPL may be on (e.g., cover or overlap) a sidewall of the inner protective layer 144B. According to some embodiments, the outer protective layer OPL may not extend to above the gate structure PGT and may not be on (e.g., not cover or not overlap) the inner protective layer 144B on the gate structure PGT. For example, the outer protective layer OPL may not be on (not cover or not overlap) an upper surface of the inner protective layer 144B. According to some embodiments, the outer protective layer OPL may extend to above the gate structure PGT to cover or overlap the inner protective layer 144B on the gate structure PGT. For example, the outer protective layer OPL may be on (e.g., cover or overlap) the upper surface of the inner protective layer 144B. A thickness of an extension of the outer protective layer OPL above the gate structure PGT may be adjusted by CMP on the outer protective layer OPL.

According to some embodiments, the outer protective layer OPL may (at least partially) extend along the inner protective layer 144B and thus may be on (e.g., cover or overlap) a portion of the upper surface of the substrate 110. For example, the outer protective layer OPL may cover (or overlap) a portion of the upper surface of the substrate 110 that is not covered (or not overlapped) by the gate structure PGT, the insulating spacer PGS, and the inner protective layer 144B. The outer protective layer OPL may be on (e.g., cover or overlap) an upper surface of the isolation layer 112. The outer protective layer OPL may contact the portion of the upper surface of the substrate 110 not covered (or not overlapped) by the gate structure PGT, the insulating spacer PGS, and the inner protective layer 144B. The outer protective layer OPL may contact the upper surface of the isolation layer 112.

According to some embodiments, the outer protective layer OPL may have a different etch rate from that of the inner protective layer 144B. That is, the outer protective layer OPL and the inner protective layer 144B may have an etch selectivity. According to some embodiments, the outer protective layer OPL may include, for example, an oxide layer, a silicon oxide layer, SiOCN, SiON, SiOC, and/or a combination thereof.

On the spacer structure SP4, an insulating filling layer 145 may be disposed. The insulating filling layer 145 may (at least partially) fill a (remaining) space not filled by the spacer structure SP4, within a space between (adjacent gate structures PGT among) the plurality of gate structures PGT. The outer protective layer OPL may extend around (e.g., at least partially surround) the insulating filling layer 145. A sidewall of the insulating filling layer 145 may be spaced apart from the inner protective layer 144B with the outer protective layer OPL interposed therebetween, and a lower end (e.g., lower surface) of the insulating filling layer 145 may be spaced apart from the substrate 110 with the outer protective layer OPL interposed therebetween.

According to some embodiments, the insulating filling layer 145 may have a different etch rate from that of the outer protective layer OPL, and may have the same (e.g., substantially the same) etch rate as that of the inner protective layer 144B. According to some embodiments, the insulating filling layer 145 may include, for example, a nitride layer or a silicon nitride layer.

The upper capping layer 146B may be disposed on the insulating filling layer 145. The upper capping layer 146B may be on (e.g., cover or overlap) an upper surface of the insulating filling layer 145, and may be on (e.g., cover or overlap) a portion of the upper surface of the spacer structure SP4 that is not covered by the insulating filling layer 145. According to some embodiments, the outer protective layer OPL may not extend to above the gate structure PGT, and the upper capping layer 146B may contact a portion (e.g., an upper surface) of the inner protective layer 144B that is not covered by the outer protective layer OPL. According to some embodiments, the outer protective layer OPL may extend to above the gate structure PGT, and the upper capping layer 146B may be spaced apart from (the upper surface of) the inner protective layer 144B with the outer protective layer OPL interposed therebetween.

According to some embodiments, the upper capping layer 146B may have a different etch rate from that of the outer protective layer OPL, and may have the same (e.g., substantially the same) etch rate as that of the insulating filling layer 145. For example, the upper capping layer 146B may include a silicon nitride layer.

A contact plug hole CPH extending in (e.g., passing through or penetrating) the upper capping layer 146B and the insulating filling layer 145 in the vertical direction Z may be disposed in the peripheral circuit area PCA. A contact plug CP may be disposed in the contact plug hole CPH, and the contact plug CP may extend along the contact plug hole CPH to the second active region AC2 of the substrate 110.

According to some embodiments, the outer protective layer OPL may extend along the inner protective layer 144B, and may contact a sidewall of the contact plug CP. According to some embodiments, a thickness d1 (in the first horizontal direction X) of the outer protective layer OPL may be within 5 nanometers to 20 nanometers. Although the outer protective layer OPL is shown as extending conformally, the outer protective layer OPL is not limited to the conformal extension. The inner protective layer 144B may be spaced apart from the contact plug CP with the outer protective layer OPL and the insulating filling layer 145 interposed therebetween. The insulating spacer PGS may be spaced apart from the contact plug CP with the outer protective layer OPL, the insulating filling layer 145, and the inner protective layer 144B interposed therebetween. In some embodiments, the outer protective layer OPL, the inner protective layer 144B, and the insulating spacer PGS may be in contact with the upper surface of the substrate 110. The insulating filling layer 145 may be spaced apart from the upper surface of the substrate 110 with the outer protective layer OPL interposed therebetween.

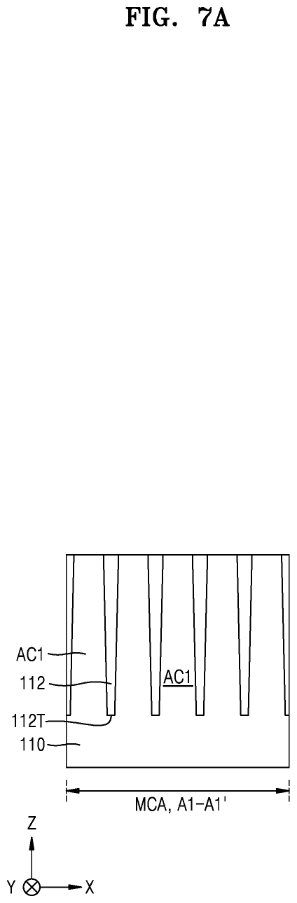

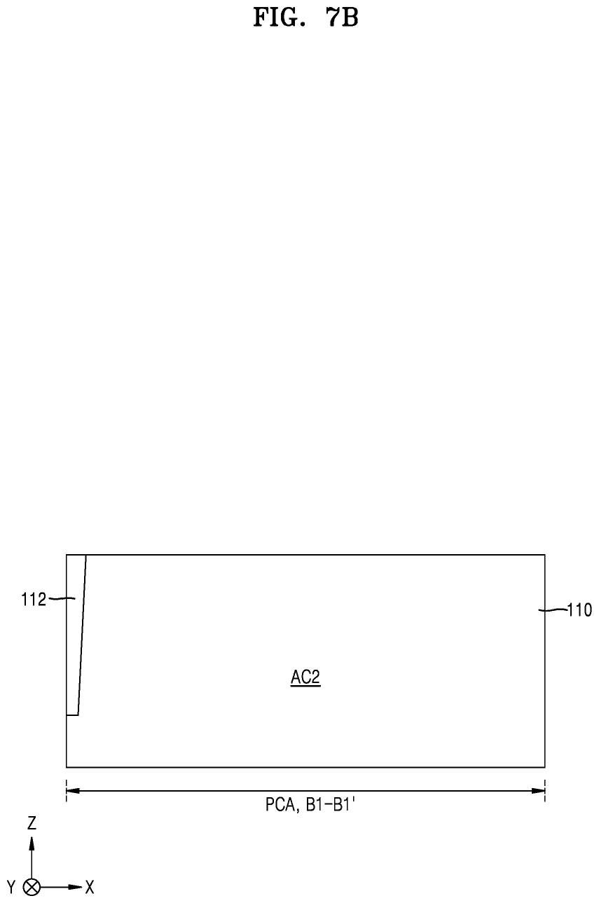

FIGS. 7A through 19A and 7B through 19B are cross-sectional views for explaining a method of manufacturing the semiconductor device 100, according to some embodiments. In detail, FIGS. 7A through 19A are cross-sectional views of some components of a partial area corresponding to a cross section taken along line A1-A1′ of FIG. 1, according to manufacturing processes, and FIGS. 7B through 19B are cross-sectional views of some components of a portion corresponding to a cross-section taken along line B1-B1′ of FIG. 1 according to manufacturing processes.

Referring to FIGS. 7A and 7B, a plurality of isolation trenches 112T and a plurality of isolation layers 112 may be formed in a substrate 110 having a cell array area MCA and a peripheral circuit area PCA to define a plurality of first active regions AC1 in the cell array area MCA of the substrate 110 and a second active region AC2 in the peripheral circuit area PCA of the substrate 110.

In the cell array area MCA of the substrate 110, a plurality of word line trenches (not shown) in line shapes extending in the first horizontal direction X in parallel to each other and crossing (overlapping) the first active region AC1 may be formed to form the plurality of word lines WL of FIG. 1, To form the plurality of word line trenches each having a step at a lower surface thereof, the isolation layer 112 and the substrate 110 may be respectively etched by separate etching processes, and thus have different etch depths. A resultant structure in which the plurality of word line trenches are formed may be cleaned, and then a dielectric material, a conductive material, and an insulating material may be formed in this stated order in each of the plurality of word line trenches. Before or after a plurality of word lines are formed, an ion implantation process may be performed to form a plurality of source/drain regions above (in) the plurality of first active regions AC1.

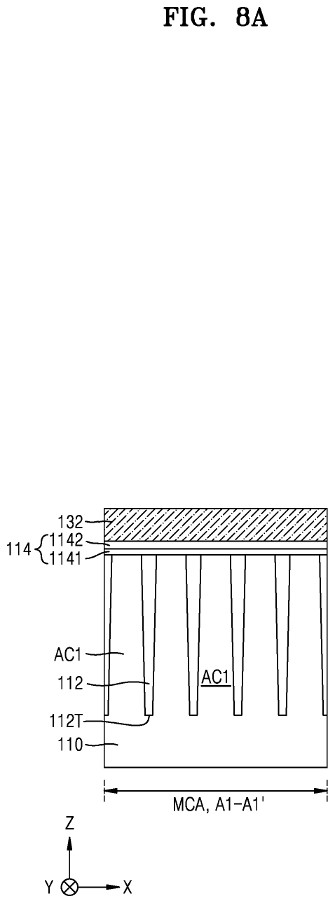

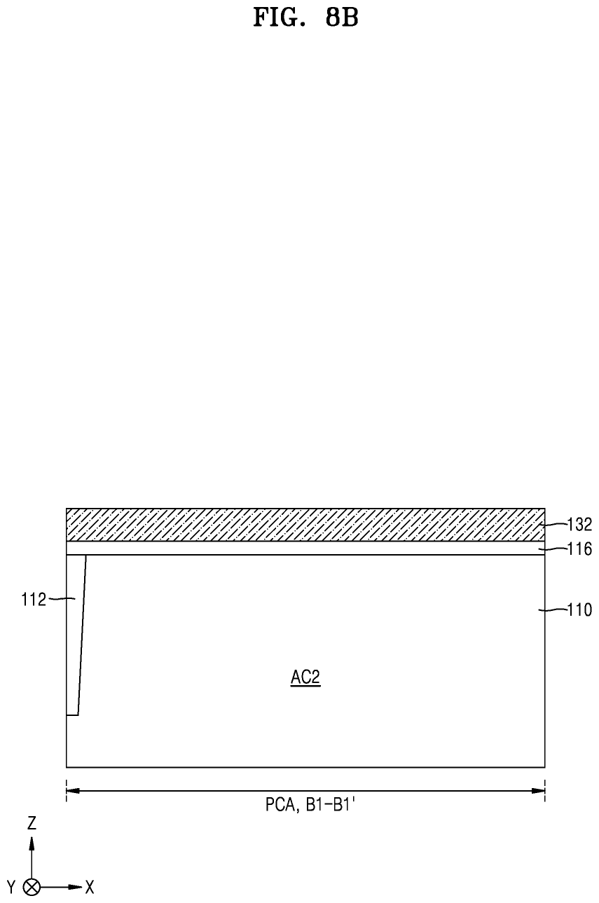

Referring to FIGS. 8A and 8B, the buffer layer 114 including a first insulating layer 1141 and a second insulating layer 1142 may be formed on the substrate 110 in the cell array area MCA, and the gate dielectric layer 116 may be formed on the substrate 110 in the peripheral circuit area PCA.

Thereafter, the lower conductive layer 132 may be formed on the buffer layer 114 in the cell array area MCA and the gate dielectric layer 116 in the peripheral circuit area PCA. According to some embodiments, the lower conductive layer 132 may include, for example, Si, Ge, W, WN, Co, Ni, A1, Mo, Ru, Ti, TiN, Ta, TaN, Cu, and/or a combination thereof. For example, the lower conductive layer 132 may include polysilicon.

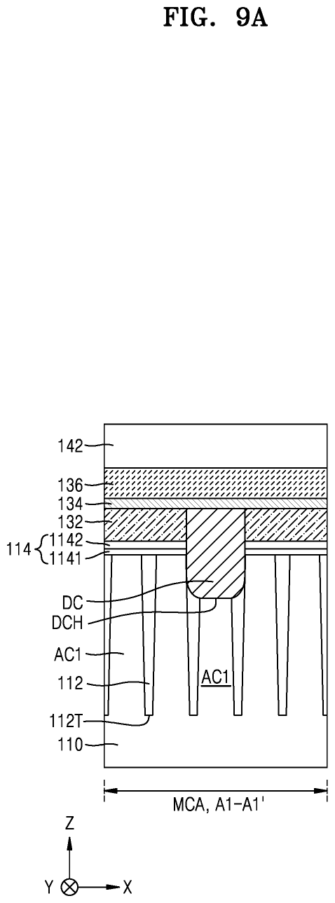

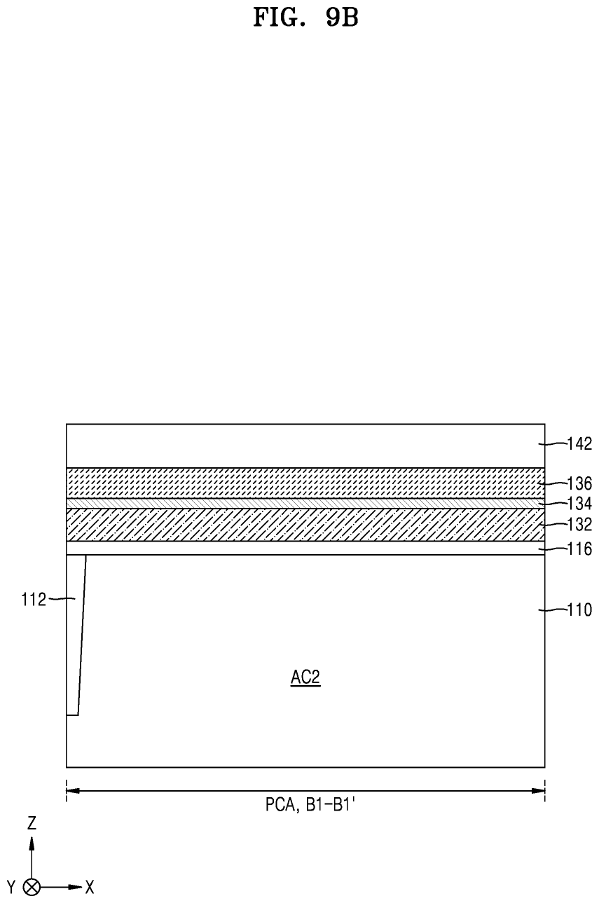

Referring to FIGS. 9A and 9B, after a first mask pattern (not shown) is formed on the lower conductive layer 132, the lower conductive layer 132 exposed through an opening (not shown) of the first mask pattern in the cell array area MCA may be etched. Thereafter, an exposed portion of the substrate 110 and a portion of the isolation layer 112 may be etched to form the direct contact plug hole DCH. A selected one among (at least one of) the first active regions AC1 of the substrate 110 may be exposed through the direct contact plug hole DCH.

Thereafter, the first mask pattern may be removed, and a direct contact DC may be formed in the direct contact plug hole DCH. In an example of a process of forming the direct contact DC, a conductive layer, which has a sufficient thickness to fill the direct contact hole DCH, may be formed in the direct contact hole DCH and on (an upper surface of) the lower conductive layer 132, and the conductive layer may be etched back such that the conductive layer remains only in the direct contact hole DCH. The conductive layer on (the upper surface of) the lower conductive layer 132 may be removed. The conductive layer may include, for example, polysilicon.

Then, in the cell array area MCA and the peripheral circuit area PCA, the intermediate conductive layer 134, the upper conductive layer 136, and the lower capping layer 142 may be formed on the lower conductive layer 132 and the direct contact DC in this stated order. According to some embodiments, each of the intermediate conductive layer 134 and the upper conductive layer 136 may include for example, TiN, TiSiN, W, W silicide, and/or a combination thereof. The lower capping layer 142 may include, for example, a silicon nitride layer.

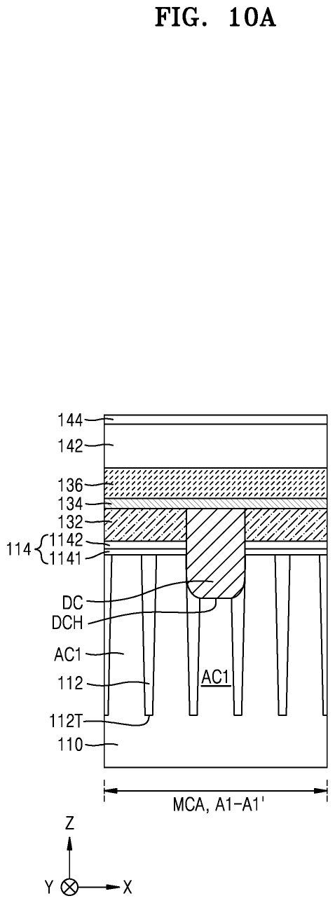

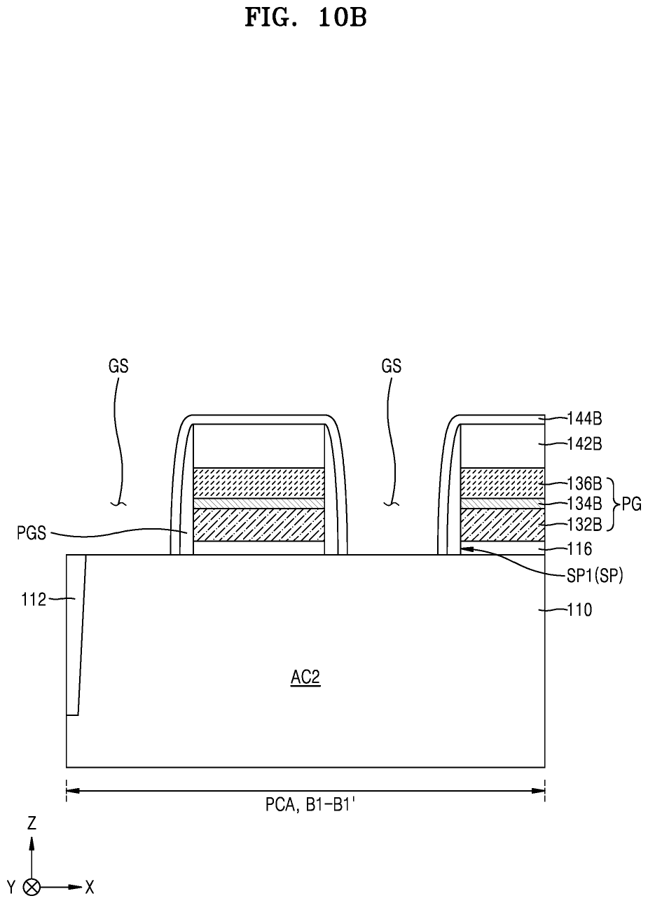

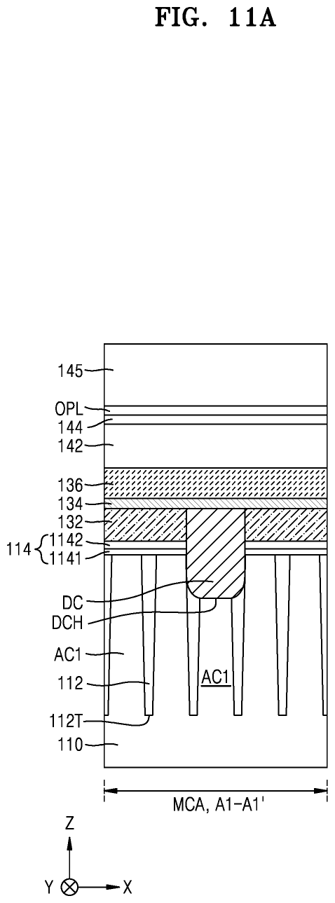

Referring to FIGS. 10A and 10B, with the cell array area MCA being covered with a mask pattern (not shown), the gate dielectric layer 116, the lower conductive layer 132, the intermediate conductive layer 134, the upper conductive layer 136, and the lower capping layer 142 may be patterned in the peripheral circuit area PCA to form the gate electrode PG consisting of the lower conductive pattern 132B, the intermediate conductive pattern 134B, and the upper conductive pattern 136B on the gate dielectric layer 116 and to form the gate capping pattern 142B on (e.g., covering or overlapping) the gate electrode PG. Thereafter, the insulating spacer PGS may be formed on both (e.g., opposite) sidewalls of the gate structure PGT that has a stacked structure of the gate dielectric layer 116, the gate electrode PG, and the gate capping pattern 142B, and an ion implantation process may be performed to form source/drain regions in the second active region AC2 on (at) both (e.g., opposite) sides of the gate structure PGT.

Then, the mask pattern covering the cell array area MCA may be removed to expose the lower capping layer 142 in the cell array area MCA. An insulating layer 144 that covers or overlap the lower capping layer 142 in the cell array area MCA and covers or overlap the gate structure PGT, the insulating spacer PGS, and an exposed portion of the upper surface of the substrate 10 in the peripheral circuit area PCA may be formed. Thereafter, the insulating layer 144 may be patterned in the peripheral circuit area PCA by using the mask pattern (not shown) to form the inner protective layer 144B covering (or overlapping) the gate structure PGT, the insulating spacer PGS, and a portion of the upper surface of the substrate 110. According to some embodiments, the inner protective layer 144B may include a silicon nitride layer.

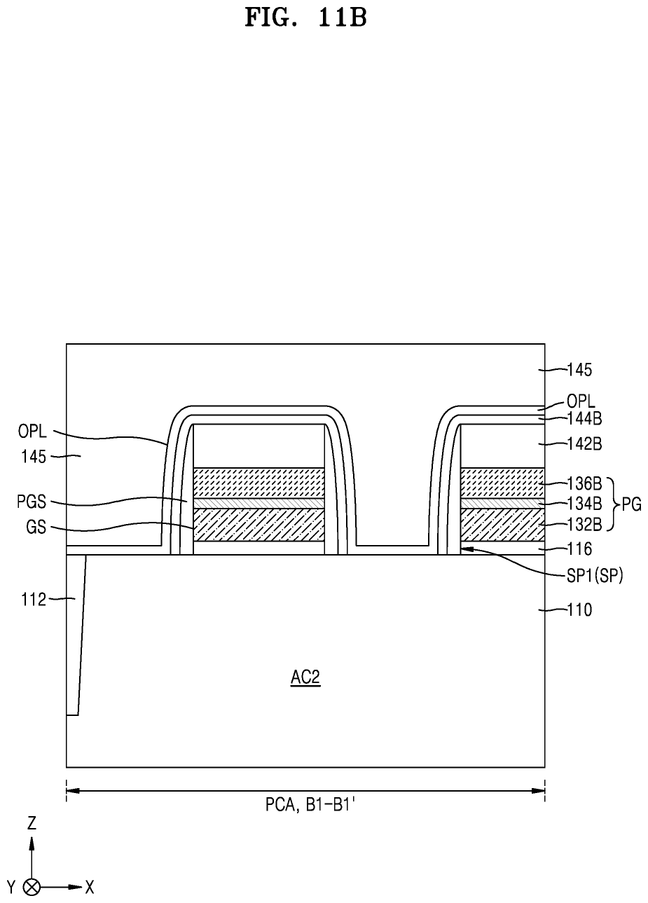

Referring to FIGS. 11A and 11B, the outer protective layer OPL may be formed to be on (e.g., to cover or to overlap) a resultant structure of FIGS. 10A and 10B. The outer protective layer OPL of the cell array area MCA may be formed on (e.g., to cover or to overlap) the insulating layer 144. The outer protective layer OPL of the peripheral circuit area PCA may be formed on (e.g., to cover or to overlap) the inner protective layer 144B and the exposed portion of the upper surface of the substrate 110. According to some embodiments, the outer protective layer OPL may have a different etch rate from that of the inner protective layer 144B. that is the outer protective layer OPL and the inner protective layer 144B may have an etch selectivity. According to some embodiments, the outer protective layer OPL may include, for example, an oxide layer, a silicon oxide layer, SiOCN, SION, SiOC, and/or a combination thereof. Terms “SiOCN”, “SiON”, and “SiOC” used herein refer to materials composed of elements respectively included in these terms, and are not chemical formulas indicating stoichiometric relationships.

The insulating filling layer 145 may be formed on the outer protective layer OPL of the cell array area MCA and the outer protective layer OPL of the peripheral circuit area PCA. The insulating filling layer 145 of the cell array area MCA may be formed to cover or overlap the outer protective layer OPL. The insulating filling layer 145 in the peripheral circuit area PCA may cover or overlap the outer protective layer OPL, and may (at least partially) fill a (remaining) space between the (adjacent) gate structures PGT that is not filled by the insulating spacer PGS, the inner protective layer 144B, and the outer protective layer OPL. According to some embodiments, the insulating filling layer 145 may have a different etch rate from that of the outer protective layer OPL, and may have the same etch rate as that of the inner protective layer 144B. According to some embodiments, the insulating filling layer 145 may include, for example, a nitride layer and/or a silicon nitride layer.

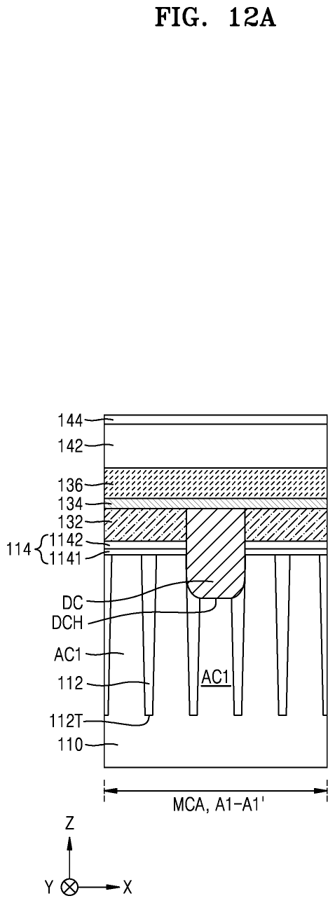

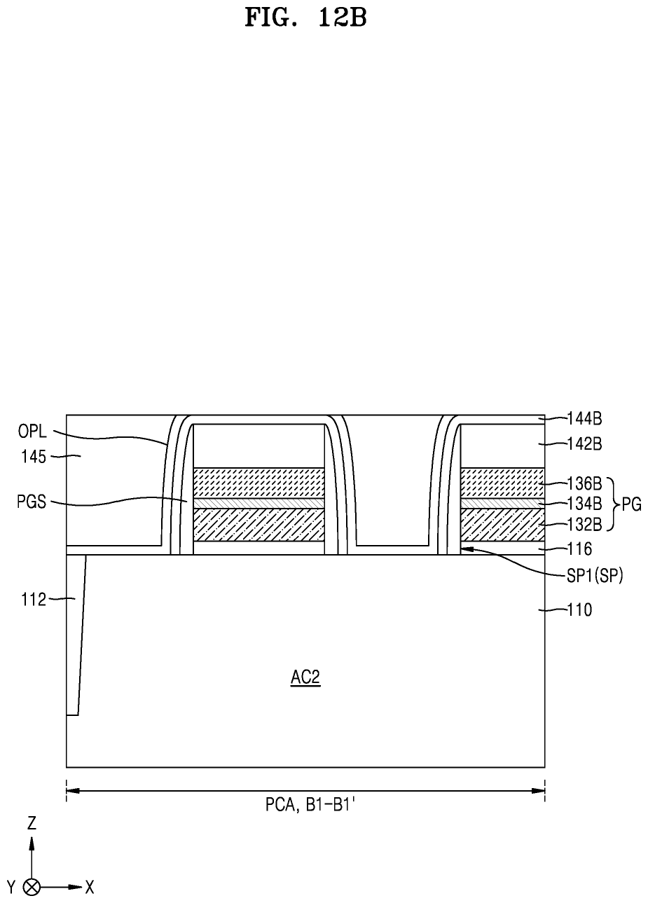

Referring to FIGS. 12A and 12B, CMP may be performed on the insulating filling layer 145 in the cell array area MCA and the peripheral circuit area PCA. The outer protective layer OPL may be exposed through the CMP on the insulating filling layer 145 in the cell array area MCA, and a portion of the outer protective layer OPL above (on) the gate structure PGT may be exposed via the CMP on the insulating filling layer 145 in the peripheral circuit area PCA. For example, at least a portion of an upper surface of the outer protective layer OPL may be exposed by the CMP on the insulating filling layer 145.

Afterwards, CMP may be performed on the outer protective layer OPL of the cell array area MCA exposed by the CMP and the outer protective layer OPL above (on) the gate structure PGT in the peripheral circuit area PCA. The insulating layer 144 may be exposed through the CMP on the outer protective layer OPL in the cell array area MCA, and a portion of the inner protective layer 144B above the gate structure PGT may be exposed via the CMP on the outer protective layer OPL above the gate structure PGT in the peripheral circuit area PCA. For example, at least a portion of an upper surface of the insulating layer 144 may be exposed by the CMP on the outer protective layer OPL.

Because the insulating filling layer 145 has a different etch rate than that of the outer protective layer OPL, the outer protective layer OPL may be used as an etch stop layer during CMP with respect to the insulating filling layer 145. Because the outer protective layer OPL has a different etch rate than that of the inner protective layer 144B, the inner protective layer 144B may be used as an etch stop layer during CMP with respect to the outer protective layer OPL.

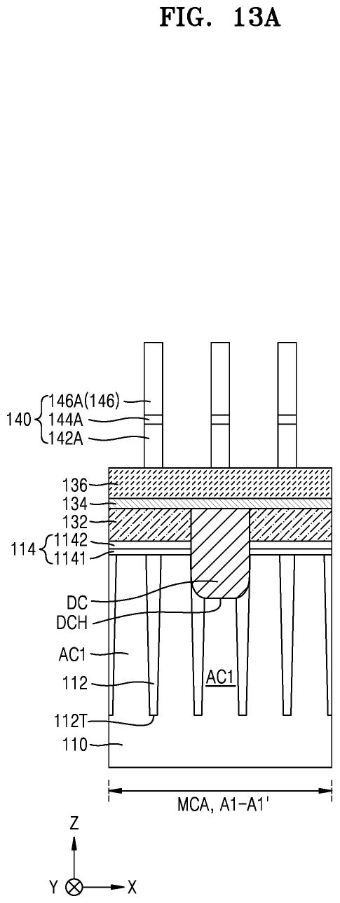

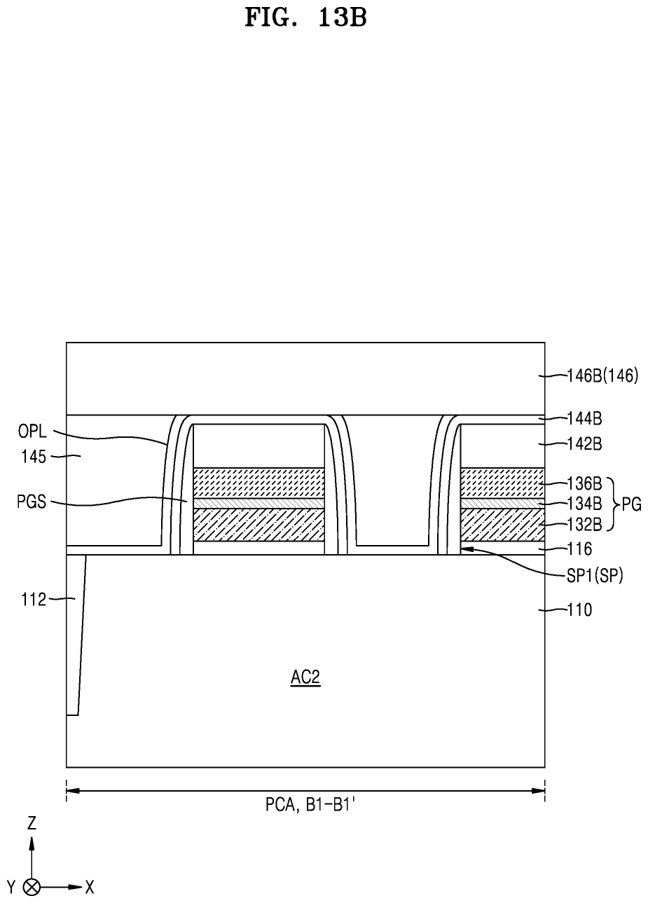

Referring to FIGS. 13A and 13B, the upper capping layer 146 on (e.g., covering or overlapping) a resultant structure having undergone the CMP of FIGS. 12A and 12B may be formed.

Afterwards, a mask pattern (not shown) may be formed on the peripheral circuit area PCA, and the upper capping layer 146, the insulating layer 144, and the lower capping layer 142 may be patterned in the cell array area MCA, thereby forming the lower capping pattern 142A, the intermediate capping pattern 144A, and the upper capping pattern 146A sequentially stacked on the upper conductive layer 136. The lower capping pattern 142A, the intermediate capping pattern 144A, and the upper capping pattern 146A are referred to as the insulating capping structure 140.

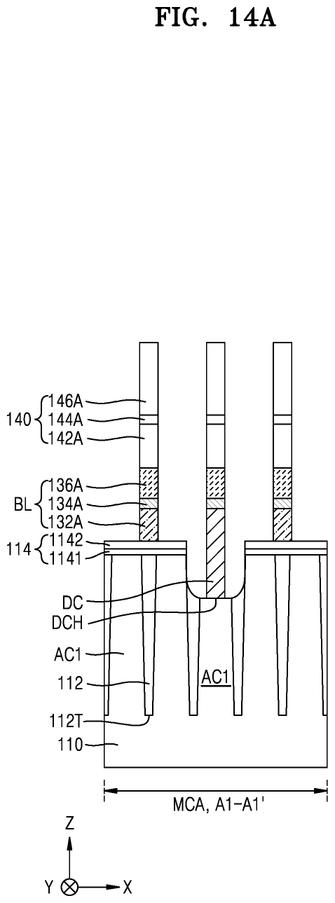

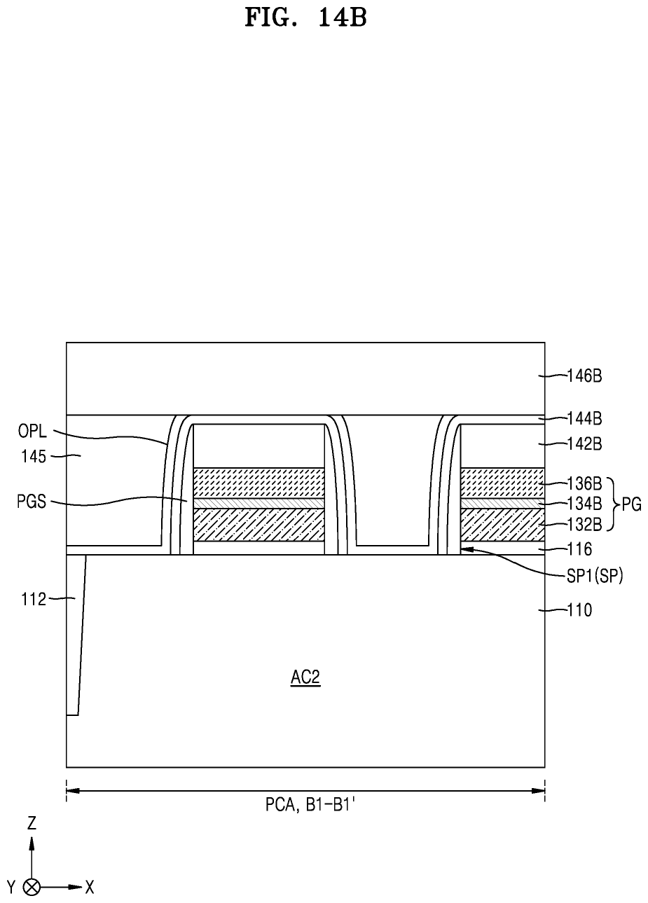

Referring to FIGS. 14A and 14B, the upper conductive layer 136, the intermediate conductive layer 134, and the lower conductive layer 132 may be etched using the lower capping pattern 142A, the intermediate capping pattern 144A, and the upper capping pattern 146A as etch masks in the cell array area MCA to form the plurality of bit lines BL composed of the lower conductive pattern 132A, the intermediate conductive pattern 134A, and the upper conductive pattern 136A.

In the process of forming the plurality of bit lines BL, a portion of the sidewall of the direct contact DC may be removed, and a portion of the direct contact plug hole DCH may be exposed.

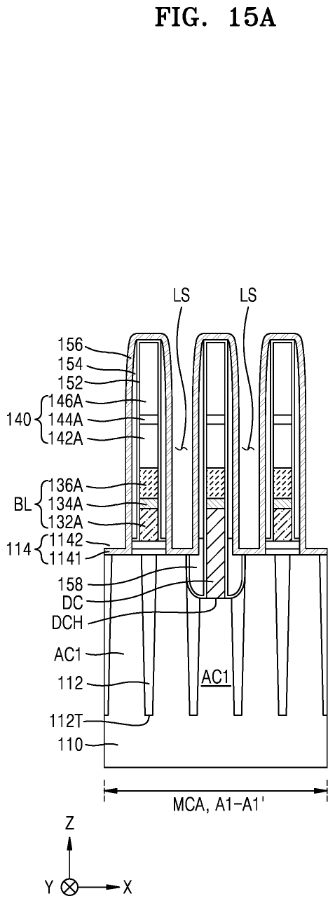

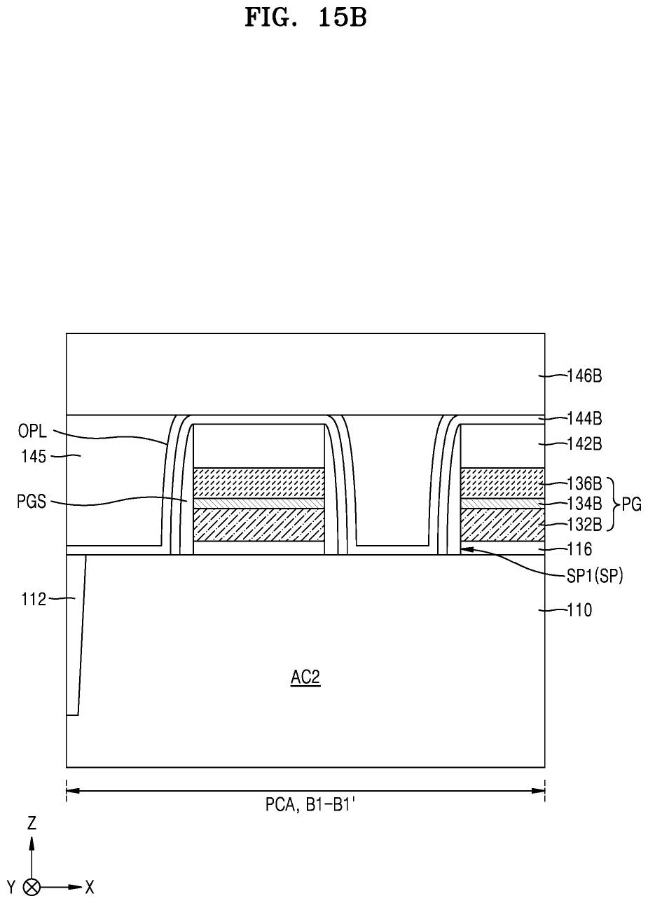

Referring to FIGS. 15A and 15B, the first spacer layer 152 may be formed on the sidewalls of the plurality of bit lines BL and the sidewall of the direct contact DC. Afterwards, an insulating layer (not shown) may be formed on the sidewalls of the plurality of bit lines BL and the sidewall of the direct contact DC to have a thickness sufficient to fill the inside of the direct contact plug hole DCH, and then anisotropically etched to leave the buried insulating layer 158 that (at least partially) fills the inside of the direct contact plug hole DCH.

The second spacer layer 154 may be formed on the sidewalls of the plurality of bit lines BL to be on (e.g., to cover or to overlap) the first spacer layer 152. A portion of the buffer layer 114 disposed between the plurality of bit lines BL may be removed using the second spacer layer 154 as an etch mask, and the upper surface of the substrate 110 may be exposed. At this time, a portion of the buried insulating layer 158 may also be removed.

Thereafter, the third spacer layer 156 may be formed on the sidewalls of the plurality of bit lines BL and the upper surface of the substrate 110.

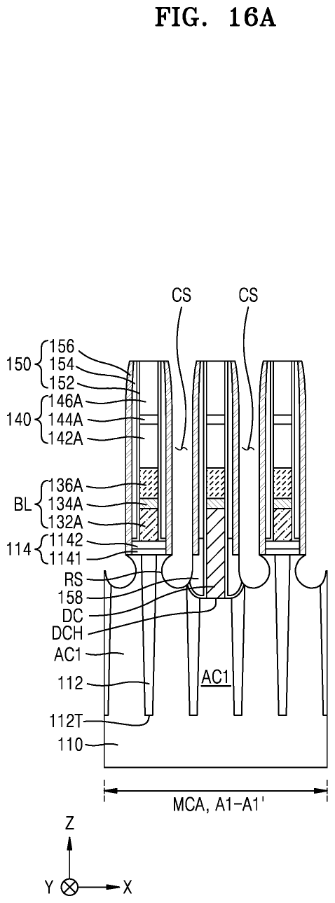

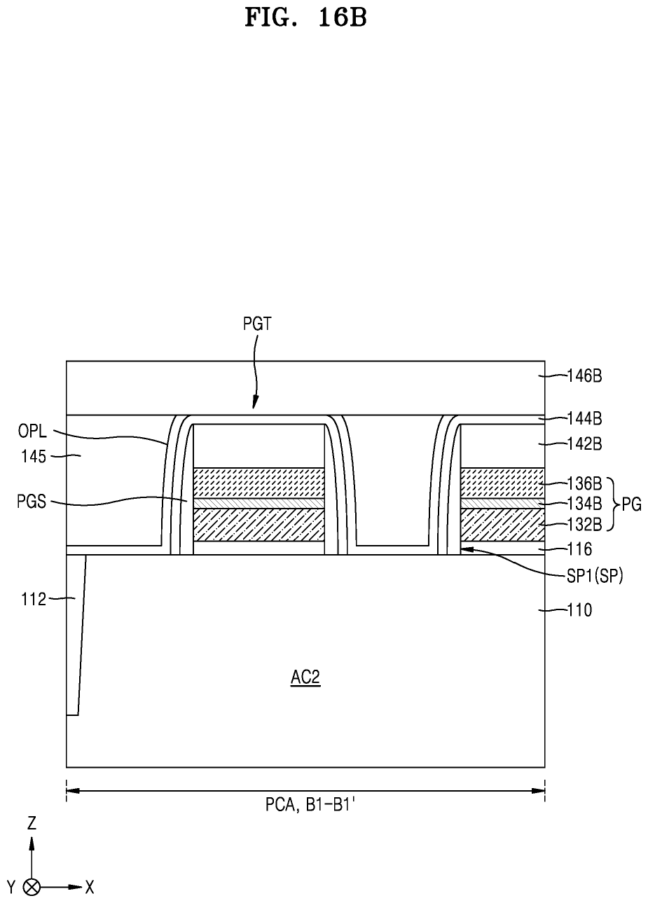

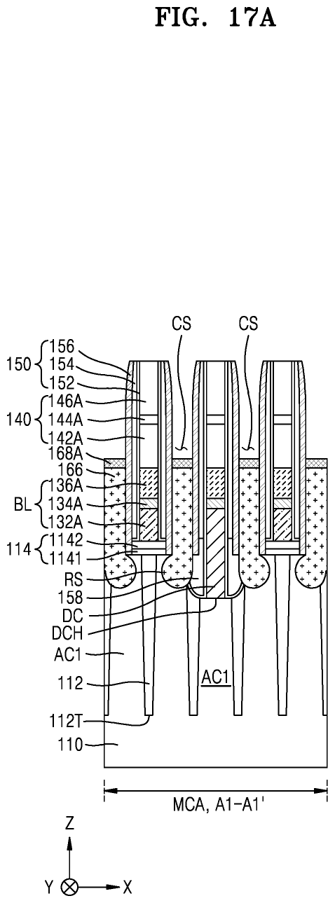

Referring to FIGS. 16A and 16B, in a resultant structure of FIGS. 15A and 15B, a plurality of insulating fences (not shown) spaced apart from each other in a line space LS in FIGS. 15A and 15B defined by the third spacer layer 156 may be formed between a pair of the plurality of bit lines BL that are adjacent to each other to separate the space defined by the third spacer layer 156 into a plurality of contact spaces CS. While the plurality of insulating fences (not shown) are being formed, respective heights of the insulating capping structure 140 and the cell spacer structure 150 may be reduced.

Thereafter, the structures exposed through the plurality of contact spaces CS may be partially removed to form the plurality of recess spaces RS exposing the first active region AC1 of the substrate 110 between a pair of the plurality of bit lines BL that are adjacent to each other. The plurality of recess spaces RS may be formed via anisotropic etching, or a combination of anisotropic etching and isotropic etching. For example, respective portions of the third spacer layer 156 and the substrate 110 below the third spacer layer 156 exposed through the plurality of contact spaces CS between the plurality of bit lines BL may be anisotropically etched, and a portion of the first active region AC1 of the substrate 110 may be isotropically etched to form the plurality of recess spaces RS. The plurality of recess spaces RS may be connected to the contact spaces CS. While an etching process for forming the contact spaces CS is being performed, respective portions of the cell spacer structure 150 and the buried insulating layer 158 may be (partially) consumed in a region adjacent to the upper surface of the substrate 110.

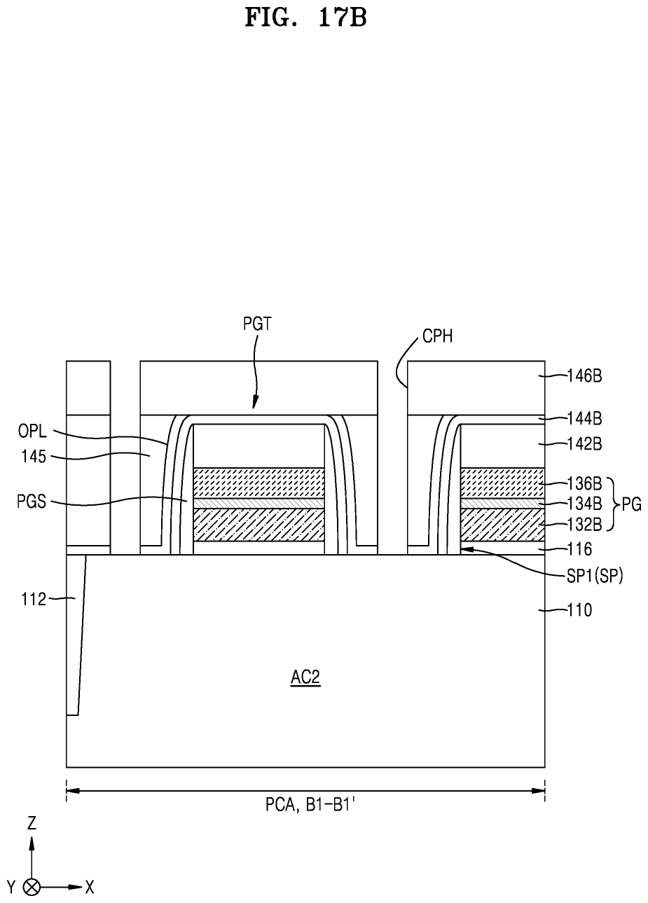

Referring to FIGS. 17A and 17B, a plurality of conductive plugs 166 may be formed to fill portions of the contact spaces CS between the plurality of bit lines BL while (at least partially) filling the plurality of recess spaces RS between the plurality of bit lines BL, in the cell array area MCA.

Thereafter, metal silicide layers 168A may be formed on the conductive plugs 166 exposed through the plurality of contact spaces CS in the cell array area MCA.

The, the plurality of contact plug holes CPH exposing the second active region AC2 of the substrate 110 may be formed in the peripheral circuit area PCA. According to some embodiments, the plurality of contact plug holes CPH may be formed by etching respective portions of the upper capping layer 146B, the insulating filling layer 145, and the outer protective layer OPL. The upper capping layer 146B, the insulating filling layer 145, and the outer protective layer OPL may be exposed through the plurality of contact plug holes CPH. For example, sidewalls of the upper capping layer 146B, sidewalls of the insulating filling layer 145, and sidewalls of the outer protective layer OPL may be exposed through the plurality of contact plug holes CPH.

The process of forming the plurality of contact plug holes CPH may be performed earlier than the process of forming the metal silicide layer 168A in the cell array area MCA. In this case, a metal silicide layer identical to the metal silicide layer 168A of the cell array area MCA may be formed along the inner wall of a contact plug hole CPH of the peripheral circuit area PCA.

According to a comparative example, in the process of etching the upper capping layer 146B and the insulating filling layer 145 to form the plurality of contact plug holes CPH, the insulating filling layer 145 may have a different etch rate from that of the upper capping layer 146B. Because the insulating filling layer 145 has a different etch rate from that of the upper capping layer 146B, diameters of a portion of the contact plug hole CPH that contacts the insulating filling layer 145 in the first horizontal direction X and the second horizontal direction Y may be greater than diameters of a portion of the contact plug hole CPH that contacts the upper capping layer 146B in the first horizontal direction X and the second horizontal direction Y. Because the diameters of the portion of the contact plug hole CPH that contacts the insulating filling layer 145 are greater than those of the portion of the contact plug hole CPH that contacts the upper capping layer 146B, a void may be formed inside a portion of the contact plug CP connected to (that contacts) the insulating filling layer 145.

According to some embodiments of the inventive concepts of the present disclosures, because the insulating filling layer 145 may have the same etch rate as that of the upper capping layer 146B, the diameters of the portion of the contact plug hole CPH that contacts the insulating filling layer 145 in the first horizontal direction X and the second horizontal direction Y may be formed to be substantially the same as those of the portion of the contact plug hole CPH that contacts the upper capping layer 146B in the first horizontal direction X and the second horizontal direction Y. Accordingly, voids may be reduced (e.g., prevented) from being formed inside the portion of the contact plug CP that contacts the insulating filling layer 145, and, ultimately, the structural stability of the semiconductor device 100 may be improved.

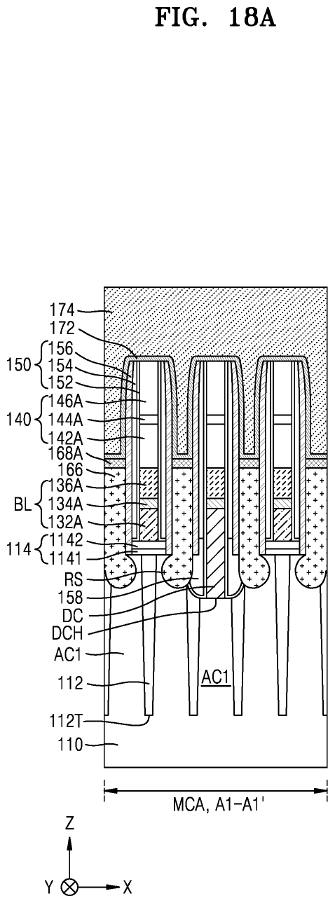

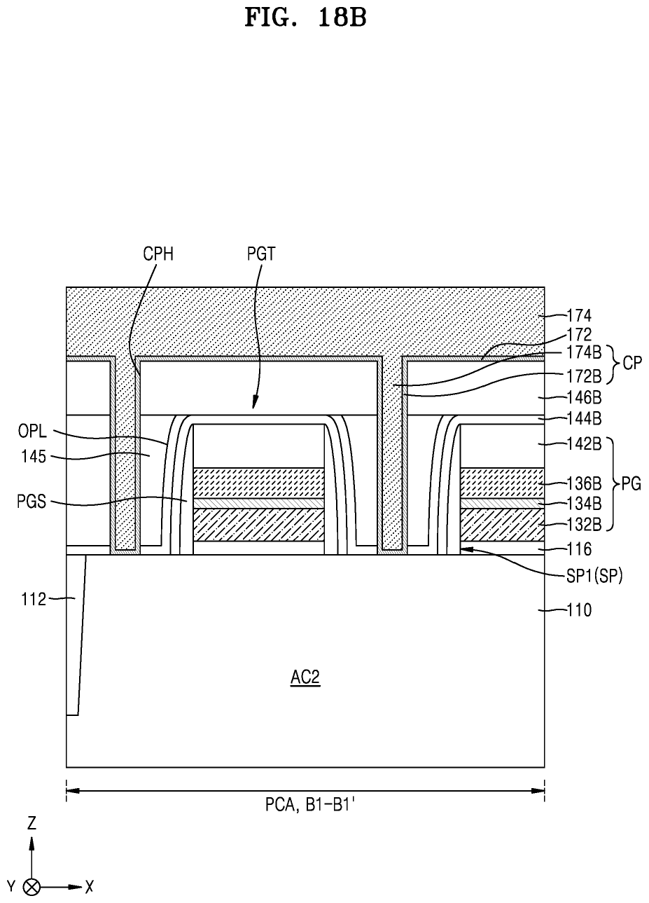

Referring to FIGS. 18A and 18B, a conductive barrier layer 172 may be formed to conformally cover (or overlap) the surface of the resultant structure of FIGS. 17A and 17B. After the conductive barrier layer 172 is formed, a conductive layer 174 on (e.g., covering or overlapping) the conductive barrier layer 172 may be formed. In the cell array area MCA, the conductive layer 174 may be formed to have a sufficient width and a sufficient height to (at least partially) fill a portion of the contact space CS between the plurality of bit lines BL. In the peripheral circuit area PCA, the conductive layer 174 may be formed to have a sufficient width and a sufficient height to (at least partially) fill the plurality of contact plug holes CPH. The conductive barrier layer 172B and the conductive layer 174B formed in the plurality of contact plug holes CPH may form a contact plug CP. The conductive layer 174B may be formed to have a sufficient width and a sufficient height to form a peri bit line, which will be described later.

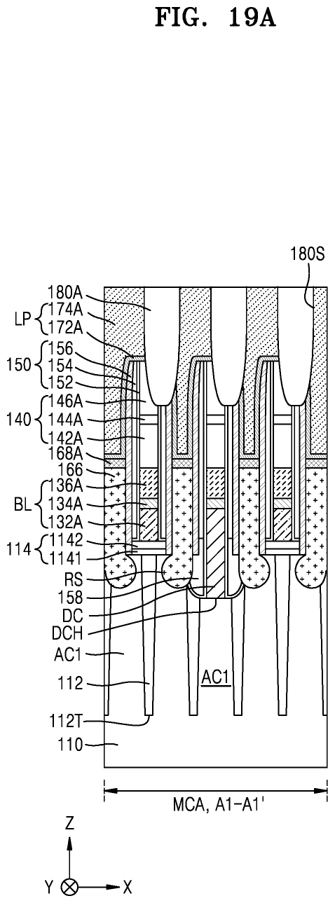

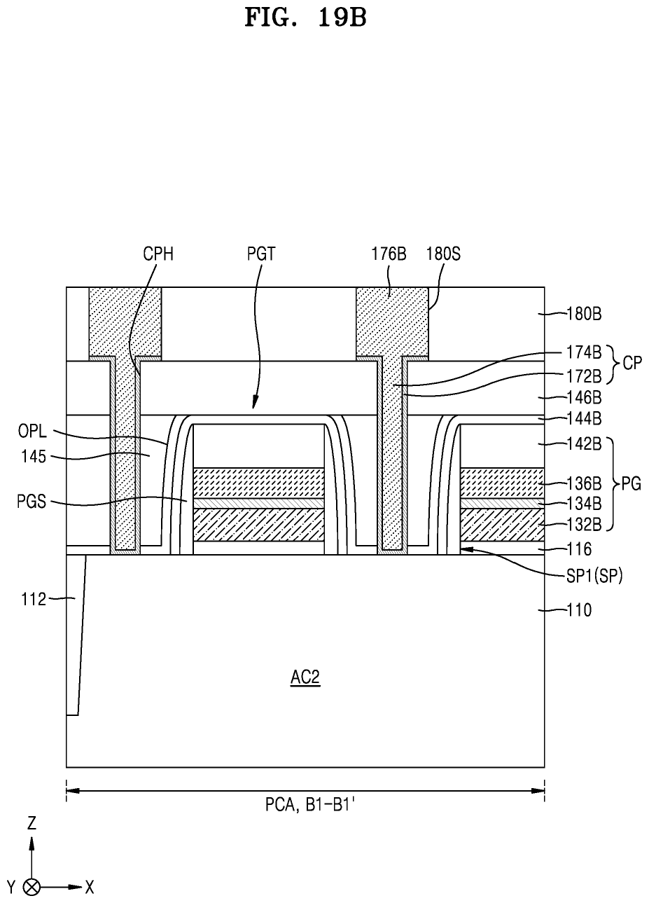

Referring to FIGS. 19A and 19B, the conductive layer 174 and the conductive barrier layer 172 may be patterned in the cell array area MCA of FIGS. 18A and 18B to form the plurality of landing pads LP. In order to form the plurality of landing pads LP, a mask pattern (not shown) may be formed to expose a portion of the conductive layer 174, and the conductive layer 174 and the conductive barrier layer 172 and extending around (e.g., at least partially surrounding) insulating layers may be etched using the mask pattern as an etch mask to form insulation spaces 180S. The mask pattern may be, but is not limited to, formed of a silicon nitride layer.

The plurality of landing pads LP may have a plurality of island-type patterns in a plan view as illustrated in FIG. 1. The plurality of landing pads LP may be formed on the metal silicide layer 168A to overlap portions of the plurality of bit lines BL in the vertical direction Z.

Thereafter, the insulating patterns 180A may be formed using an insulating material on the inner walls of the insulation spaces 180S in the cell array area MCA. The insulating patterns 180A may be formed by, for example, spin coating, chemical vapor deposition (CVD), or flowable CVD.

Thereafter, a capacitor lower electrode (not shown) may be formed on the plurality of landing pads LP in the cell array area MCA.

By patterning the conductive layer 174 and the conductive barrier layer 172 in the peripheral circuit area PCA of FIGS. 18A and 18B, the plurality of peri bit lines 176B connected (e.g., electrically connected) to the plurality of contact plugs CP may be formed. In order to form the plurality of peri bit lines 176B, a mask pattern (not shown) may be formed to expose a portion of the conductive layer 174, and the conductive layer 174 and the conductive barrier layer 172 and extending around (e.g., at least partially surrounding) insulating layers may be etched using the mask pattern as an etch mask to form the insulation spaces 180S. The mask pattern may be, but is not limited to, formed of a silicon nitride layer. The plurality of peri bit lines 176B may be spaced apart (e.g., insulated) from each other by the insulating patterns 180B formed within the insulation spaces 180S.

While the inventive concept has been particularly shown and described with reference to embodiments thereof, it will be understood that various changes in form and details may be made therein without departing from the scope of the following claims.

What is claimed is:

1. A semiconductor device comprising:
a substrate;
a plurality of gate structures on the substrate, wherein the plurality of gate structures includes a first gate structure and a second gate structure that is adjacent the first gate structure;
spacer structures on opposite sidewalls of the first gate structure;
wherein the spacer structures comprise:
insulating spacers on the opposite sidewalls of the first gate structure;
an inner protective layer on the insulating spacers and an upper surface of the first gate structure; and
an outer protective layer on at least a portion of the inner protective layer,
an insulating filling layer on the spacer structures, wherein the insulating filling layer is between the first gate structure and the second gate structure; and
an upper capping layer on an upper surface of the insulating filling layer,
wherein the upper capping layer includes a same material as the insulating filling layer.

2. The semiconductor device of claim 1, wherein the outer protective layer includes an oxide layer, a silicon oxide layer, SiOCN, SiON, and/or SiOC.

3. The semiconductor device of claim 1, wherein the inner protective layer includes a nitride layer and/or a silicon nitride layer.

4. The semiconductor device of claim 1, wherein the insulating filling layer includes a nitride layer and/or a silicon nitride layer.

5. The semiconductor device of claim 1, wherein
the outer protective layer is on an upper surface of the substrate, and
the insulating filling layer has a sidewall that is spaced apart from the inner protective layer with the outer protective layer interposed therebetween, and the insulating filling layer has a lower surface spaced apart from the upper surface of the substrate with the outer protective layer interposed therebetween.

6. The semiconductor device of claim 5, further comprising a contact plug that extends in the upper capping layer and the insulating filling layer in a first direction that is perpendicular to the upper surface of the substrate,
wherein the outer protective layer comprises:
a side portion that extends along the inner protective layer; and
a lower portion that extends from the side portion of the outer protective layer to the contact plug along the upper surface of the substrate, and
the lower portion of the outer protective layer contacts a sidewall of the contact plug.

7. The semiconductor device of claim 1, wherein
the outer protective layer is on an upper surface of the substrate,
the outer protective layer extends along the inner protective layer to be on the upper surface of the substrate, and
a sidewall of the insulating filling layer is spaced apart from the inner protective layer with the outer protective layer interposed therebetween, and a lower surface of the insulating filling layer is spaced apart from the upper surface of the substrate with the outer protective layer and the inner protective layer interposed therebetween.

8. The semiconductor device of claim 7, further comprising a contact plug that extends in the upper capping layer and the insulating filling layer in a first direction that is perpendicular to the upper surface of the substrate,
wherein the outer protective layer comprises:
a side portion that extends along the inner protective layer; and
a lower portion that extends from the side portion of the outer protective layer to the contact plug along the upper surface of the substrate, and
the lower portion of the outer protective layer contacts a sidewall of the contact plug.

9. The semiconductor device of claim 1, wherein the insulating filling layer contacts an upper surface of the substrate.

10. The semiconductor device of claim 9, further comprising a contact plug that extends in the insulating filling layer and the upper capping layer in a first direction that is perpendicular to the upper surface of the substrate,
wherein a sidewall of the contact plug is spaced apart from the outer protective layer with the insulating filling layer interposed therebetween.

11. A semiconductor device comprising:
a substrate;
a plurality of gate structures on the substrate;
spacer structures on opposite sidewalls of the plurality of gate structures, respectively;
wherein the spacer structures comprise:
a plurality of insulating spacers on the opposite sidewalls of the plurality of gate structures, respectively;
an inner protective layer on the plurality of insulating spacers and upper surfaces of the plurality of gate structures; and
an outer protective layer on at least a portion of the inner protective layer,
an insulating filling layer between adjacent gate structures among the plurality of gate structures, wherein the insulating filling layer is on the spacer structures;
an upper capping layer on an upper surface of the insulating filling layer; and
a contact plug that extends in the insulating filling layer and the upper capping layer in a first direction that is perpendicular to an upper surface of the substrate,
wherein the outer protective layer includes an oxide layer, a silicon oxide layer, SiOCN, SiON, and/or SiOC.

12. The semiconductor device of claim 11, wherein the insulating filling layer includes a same material as the upper capping layer.

13. The semiconductor device of claim 11, wherein the insulating filling layer includes a nitride layer and/or a silicon nitride layer.

14. The semiconductor device of claim 11, wherein the contact plug comprises:
a conductive barrier layer that extends along an inner wall of a contact plug hole; and
a conductive layer that at least partially fills a remaining space in the contact plug hole.

15. The semiconductor device of claim 11, wherein
the outer protective layer extends along the inner protective layer to be on a portion of the upper surface of the substrate, and
a sidewall of the insulating filling layer is spaced apart from the inner protective layer with the outer protective layer interposed therebetween, and a lower surface of the insulating filling layer is spaced apart from the upper surface of the substrate with the outer protective layer interposed therebetween.

16. The semiconductor device of claim 11, wherein
the outer protective layer extends along the inner protective layer to be on the upper surface of the substrate, and
a sidewall of the insulating filling layer is spaced apart from the inner protective layer with the outer protective layer interposed therebetween, and a lower surface of the insulating filling layer is spaced apart from the upper surface of the substrate with the outer protective layer and the inner protective layer interposed therebetween.

17. A semiconductor device comprising:
a substrate;
a plurality of gate structures on the substrate;
spacer structures on opposite sidewalls of the plurality of gate structures, respectively;
wherein the spacer structures comprise:
a plurality of insulating spacers on the opposite sidewalls of the plurality of gate structures, respectively;
an inner protective layer on the plurality of insulating spacers and upper surfaces of the plurality of gate structures; and
an outer protective layer on at least a portion of the inner protective layer,
an insulating filling layer between adjacent gate structures among the plurality of gate structures, wherein the insulating filling layer is on the spacer structures;
an upper capping layer on the insulating filling layer; and
a contact plug that extends in the insulating filling layer and the upper capping layer in a first direction that is perpendicular to an upper surface of the substrate,
wherein the insulating filling layer includes a same material as the upper capping layer, and
the insulating filling layer includes a nitride layer and/or a silicon nitride layer.

18. The semiconductor device of claim 17, wherein the outer protective layer includes an oxide layer, a silicon oxide layer, SiOCN, SiON, and/or SiOC.

19. The semiconductor device of claim 17, wherein
the outer protective layer extends along the inner protective layer to be on the upper surface of the substrate, and
a sidewall of the insulating filling layer is spaced apart from the inner protective layer with the outer protective layer interposed therebetween, and a lower surface of the insulating filling layer is spaced apart from the upper surface of the substrate with the outer protective layer interposed therebetween.

20. The semiconductor device of claim 17, wherein the insulating filling layer contacts the upper surface of the substrate.
